(19) United States
(12) Patent Application Publication
(10) Pub. No.: US 2025/0045498 A1
(43) Pub. Date: Feb. 6, 2025

(54) APPARATUS AND METHODS FOR DETERMINING AND SOLVING DESIGN PROBLEMS USING MACHINE-LEARNING

(71) Applicant: D.TO, Inc., Wellesley Hills, MA (US)

(72) Inventors: Youngjin Lee, Wellesley Hills, MA (US); Juhun Lee, Framingham, MA (US)

(73) Assignee: D.TO, Inc., Wellesley Hills, MA (US)

(21) Appl. No.: 18/798,245

(22) Filed: Aug. 8, 2024

Related U.S. Application Data
(63) Continuation-in-part of application No. 18/143,281, filed on May 4, 2023, now Pat. No. 12,093,615.
(60) Provisional application No. 63/338,652, filed on May 5, 2022.

(51) Int. Cl. G06F 30/27; G06F 30/13

(52) U.S. Cl. CPC G06F 30/27; G06F 30/13

(57) ABSTRACT

An apparatus and method for determining and solving design problems is illustrated herein. Apparatus includes a processor and a database of components by manufacturer. The processor is configured to receive a representative part model which may include 2D prints and 3D models of a building design. The processor is configured to identify and categorize the representative part model to a design problem and generate design solutions to solve the design problem. The processor is also configured to encode layers of required information for a first machine-learning module. The processor determines components from the database of components, as a function of the design solution.

### CROSS-REFERENCE TO RELATED APPLICATIONS

This application is a continuation-in-part of Non-provisional application Ser. No. 18/143,281, filed on May 4, 2023, and titled “APPARATUS AND METHODS FOR DETERMINING AND SOLVING DESIGN PROBLEMS USING MACHINE-LEARNING,” which claims the benefit of priority of U.S. Provisional Patent Application Ser. No. 63/338,652, filed on May 5, 2022, and titled “APPARATUS AND METHODS FOR DETERMINING AND SOLVING DESIGN PROBLEMS USING MACHINE-LEARNING,” each of which is incorporated by reference herein in its entirety.

### FIELD OF THE INVENTION

The present invention generally relates to the field of architecture design. In particular, the present invention is directed to apparatus and methods for determining and solving design problems using machine-learning.

### BACKGROUND

The introduction of Building Information Modeling (BIM) enabled 3D modeling with building information embedded. However, BIM did not improve efficiency during the mid-late phases in the architecture design process, such as design development and construction documentation. As a result, designers are still relying on exhaustive searches and manual drafting tasks. The mid-late phases take up more than 60% of the entire project time and cost. There is a need to develop practical software that offers design guidance and a database of design references.

### SUMMARY OF THE DISCLOSURE

In an aspect, an apparatus for determining and solving design problems using machine learning is disclosed. The apparatus includes at least a processor and a memory communicatively connected to the at least a processor, the memory containing instructions configuring the at least a processor to receive a representative part model, determine at least a part feature of the representative part model, categorize the representative part model to a part progress class label that defines a region class and a design progress state, wherein the categorizing the representative part model includes determining the region class as a function of a design reference, wherein the design reference is queried from a part database as a function of the at least a part feature and the design reference includes design standards and determining the design progress state as a function of the design reference using a first machine-learning module, determine at least a design problem of the representative part model with the part progress class label, generate at least a design solution as a function of the at least a design problem using a second machine-learning module and generate a user interface displaying the representative part model with the part progress class label, the at least a design problem, and the at least a design solution on a remote device.

In another aspect, a method for determining and solving design problems using machine learning is disclosed. The method includes receiving, using at least a processor, a representative part model, determining, using the at least a processor, at least a part feature of the representative part model, categorizing, using the at least a processor, the representative part model to a part progress class label that defines a region class and a design progress state, wherein the categorizing the representative part model includes determining the region class as a function of a design reference, wherein the design reference is queried from a part database as a function of the at least a part feature and the design reference includes design standards and determining the design progress state as a function of the design reference using a first machine-learning module, determining, using the at least a processor, at least a design problem of the representative part model with the part progress class label, generating, using the at least a processor, at least a design solution as a function of the at least a design problem using a second machine-learning module and generating, using the at least a processor, a user interface displaying the representative part model with the part progress class label, the at least a design problem, and the at least a design solution on a remote device.

These and other aspects and features of non-limiting embodiments of the present invention will become apparent to those skilled in the art upon review of the following description of specific non-limiting embodiments of the invention in conjunction with the accompanying drawings.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 illustrates a block diagram of an exemplary apparatus for determining and solving design problems using artificial intelligence;

FIG. 2 illustrates an exemplary user interface displaying a design solution for a design problem;

FIG. 3 illustrates an exemplary user interface displaying a component database used to select components for a representative part model;

FIG. 4 illustrates an exemplary user interface displaying a click and drop feature;

FIG. 5 illustrates a flow diagram of an exemplary apparatus according to the subject disclosure;

FIG. 6 illustrates a block diagram of an exemplary machine-learning module;

FIG. 7 illustrates a diagram of an exemplary neural network;

FIG. 8 illustrates a block diagram of an exemplary node in a neural network;

FIG. 9 illustrates a diagram of an exemplary embodiment of a fuzzy set comparison;

FIG. 10 illustrates a diagram of an exemplary chatbot system;

FIG. 11 illustrates an exemplary user interface displaying a plurality of part features of a representative part model and a plurality of part progress class labels of a plurality of building parts;

FIG. 12 illustrates an exemplary user interface displaying a representative part model and a plurality of design assist datums;

FIG. 13 illustrates a flow diagram illustrating an exemplary embodiment of a method for determining and solving design problems using machine-learning;

FIG. 14 illustrates a flow diagram illustrating an exemplary embodiment of another method for determining and solving design problems using machine-learning; and

FIG. 15 illustrates a block diagram of a computing system that can be used to implement any one or more of the methodologies disclosed herein and any one or more portions thereof.

The drawings are not necessarily to scale and may be illustrated by phantom lines, diagrammatic representations and fragmentary views. In certain instances, details that are not necessary for an understanding of the embodiments or that render other details difficult to perceive may have been omitted.

### DETAILED DESCRIPTION

At a high level, aspects of the present disclosure are directed to apparatus and methods that guide a user through the requirements of building assembly design through the use of machine-learning. Aspects of the present disclosure may consider complex conditions of various building materials, constructability, or the like to suggest potential design changes to a model.

Aspects of the present disclosure can be used to help complete construction drawings by eliminating any labor-intensive drafting tasks. Exemplary embodiments illustrating aspects of the present disclosure are described below in the context of several specific examples.

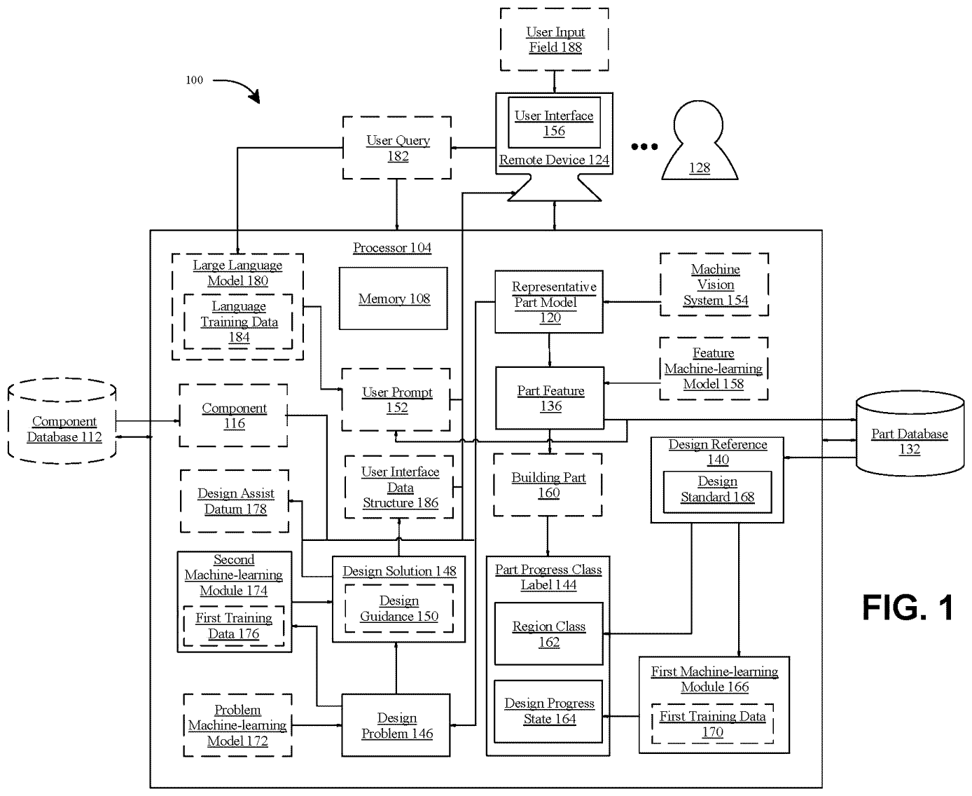

Referring now to FIG. 1, an exemplary embodiment of an apparatus 100 for determining and solving design problems using machine learning is illustrated. Apparatus 100 includes a processor 104. Processor 104 may include any computing device as described in this disclosure, including without limitation a microcontroller, microprocessor, digital signal processor (DSP) and/or system on a chip (SoC) as described in this disclosure. Computing device may include, be included in, and/or communicate with a mobile device such as a mobile telephone or smartphone. Processor 104 may include a single computing device operating independently, or may include two or more computing device operating in concert, in parallel, sequentially or the like; two or more computing devices may be included together in a single computing device or in two or more computing devices. Processor 104 may interface or communicate with one or more additional devices as described below in further detail via a network interface device. Network interface device may be utilized for connecting processor 104 to one or more of a variety of networks, and one or more devices. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network may employ a wired and/or a wireless mode of communication. In general, any network topology may be used. Information (e.g., data, software etc.) may be communicated to and/or from a computer and/or a computing device. Processor 104 may include but is not limited to, for example, a computing device or cluster of computing devices in a first location and a second computing device or cluster of computing devices in a second location. Processor 104 may include one or more computing devices dedicated to data storage, security, distribution of traffic for load balancing, and the like. Processor 104 may distribute one or more computing tasks as described below across a plurality of computing devices of computing device, which may operate in parallel, in series, redundantly, or in any other manner used for distribution of tasks or memory between computing devices. Processor 104 may be implemented using a “shared nothing” architecture in which data is cached at the worker, in an embodiment, this may enable scalability of apparatus 100 and/or computing device.

With continued reference to FIG. 1, processor 104 may be designed and/or configured to perform any method, method step, or sequence of method steps in any embodiment described in this disclosure, in any order and with any degree of repetition. For instance, processor 104 may be configured to perform a single step or sequence repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. Processor 104 may perform any step or sequence of steps as described in this disclosure in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

With continued reference to FIG. 1, apparatus 100 includes a memory 108 communicatively connected to processor 104. For the purposes of this disclosure, “communicatively connected” means connected by way of a connection, attachment or linkage between two or more relata which allows for reception and/or transmittance of information therebetween. For example, and without limitation, this connection may be wired or wireless, direct or indirect, and between two or more components, circuits, devices, systems, and the like, which allows for reception and/or transmittance of data and/or signal(s) therebetween. Data and/or signals therebetween may include, without limitation, electrical, electromagnetic, magnetic, video, audio, radio and microwave data and/or signals, combinations thereof, and the like, among others. A communicative connection may be achieved, for example and without limitation, through wired or wireless electronic, digital or analog, communication, either directly or by way of one or more intervening devices or components. Further, communicative connection may include electrically coupling or connecting at least an output of one device, component, or circuit to at least an input of another device, component, or circuit. For example, and without limitation, via a bus or other facility for intercommunication between elements of a computing device. Communicative connecting may also include indirect connections via, for example and without limitation, wireless connection, radio communication, low power wide area network, optical communication, magnetic, capacitive, or optical coupling, and the like. In some instances, the terminology “communicatively coupled” may be used in place of communicatively connected in this disclosure.

With continued reference to FIG. 1, apparatus 100 may include a component database 112 related to components 116 from a plurality of manufacturers. Component database 112 may be implemented, without limitation, as a relational database, a key-value retrieval database such as a NOSQL database, or any other format or structure for use as a database that a person skilled in the art would recognize as suitable upon review of the entirety of this disclosure. Component database 112 may alternatively or additionally be implemented using a distributed data storage protocol and/or data structure, such as a distributed hash table or the like. Component database 112 may include a plurality of data entries and/or records as described above. Data entries in a database may be flagged with or linked to one or more additional elements of information, which may be reflected in data entry cells and/or in linked tables such as tables related by one or more indices in a relational database. Persons skilled in the art, upon reviewing the entirety of this disclosure, will be aware of various ways in which data entries in a database may store, retrieve, organize, and/or reflect data and/or records as used herein, as well as categories and/or populations of data consistently with this disclosure. A component database 112 may include design-based products from a plurality of manufacturers. A component database 112 may include products and materials relating to the products. Components 116 may include building materials such as aluminum composite metal panels, insulation, I-beams, or the like. Manufactures may opt-in to providing component database 112 with components that they provide. Component database 112 may also include information on manufactures, such as location, phone number, email, and/or other contact information. Component database 112 may store a description of the manufacturer that may be submitted to the component database 112 by the manufacturer. Component database 112 may be communicatively connected to processor 104. Component database 112 may be used by apparatus 100 to suggest products to users of apparatus 100 during a design process. Manufacturers may use add their products and/or components into component database 112 as a way to market to users that may use the building components.

With continued reference to FIG. 1, processor 104 is configured to receive a representative part model 120. Representative part model 120 may include a plurality of sides. A “representative part model,” as used in this disclosure, is a representation of a part to be manufactured or built. The part may include any item made of materials such as metals including, for example, aluminum and steel alloys, brass, and the like, plastics, such as nylon, acrylic, ABS, Delrin, polycarbonate, and the like, foam, composites, wood, etc. As a non-limiting example, part may include architectural component or element; for instance a building component. Representative part model 120 may include any data describing and/or relating to a computer model of a part to be manufactured. In some cases, representative part model 120 may contain data in the form of an STL file, an OBJ FILE, an FBX file and any other file suitable for representative part models. In some cases, representative part model 120 may contain data in any form suitable for use in other design software such as, and without limitation, Revit, ArchiCAD, Rhino, AutoCAD, and/or any other applicable design software. A “computer model,” as described herein, is a digital model of a physical structure. In a non-limiting example, computer model may be as created using building information modeling (BIM). BIM models may cover spatial relationships, geospatial information, quantities and properties of building components (for example, manufacturers' details), and enables a wide range of collaborative processes relating to the built asset from initial planning through to construction and then throughout its operational life. BIM models for the purposes of this disclosure may include any models and/or objects that may be generated and/or created using any design software. For example, a BIM model may include a model created by a design software such as AutoCAD.

With continued reference to FIG. 1, representative part model 120 may include a plurality of sides. Each side of plurality of sides, as used in this disclosure, may include a view of representative part model 120 from a plane orthogonal to an axis passing through an origin of representative part model 120. The axis may include, as a non-limiting example, a three-axis coordinate system, such as the x-axis, y-axis, and z-axis, or abscissa, ordinate, and applicate. The axis may include, as a further non-limiting example, any axis passing through an origin of the representative part model. Persons skilled in the art, upon reviewing the entirety of this disclosure, will be aware of axis which may be suitable for use as each side of the plurality of sides consistently with this disclosure. The origin of the representative part model, as described herein, is a fixed point of reference for the representative part model 120. For example and without limitation, the origin may include the center of mass, the geometric center, the center of a feature of the part, wherein a feature may be a hole, a well, a groove, a pocket, a channel, extruded volume, and the like. As a further example and without limitation, the origin may include any position of the representative part model. In some embodiments, the representative part model 120 may include physical example of the part to manufactured.

With continued reference to FIG. 1, in some embodiments, representative part model 120 may include a print. A “print” as used herein, is a two-dimensional drawing of a representative part model 120. As used in this disclosure, “two-dimensional” means having, appearing to have, or displaying two out of the three dimensions. In a non-limiting example, representative part model 120 may include image, document, and the like. For example, and without limitation, representative part model 120 may include portable document format (PDF). Print may be a section of the representative part model. In an embodiment, print may be a portion of a wall of a building. In some embodiments, representative part model 120 may include semantic information of a part to be built. Print may include semantic information of representative part model 120. Semantic information may include measurements or dimensions of different walls and building components. Semantic information may include information on different materials of the components of the print. Semantic information may include tolerancing and dimensioning of various components of the print.

With continued reference to FIG. 1, in some embodiments, processor 104 may receive representative part model 120 from a remote device 124. For the purposes of this disclosure, a “remote device” is an external device to a processor 104. As a non-limiting example, remote device 124 may include a smartphone, tablet, laptop, or the like. In some embodiments, remote device 124 may include an interface configured to receive inputs from a user 128. In some embodiments, user 128 may manually input any data into apparatus 100 using remote device 124. In some embodiments, user 128 may have a capability to process, store or transmit any information independently. For the purposes of this disclosure, a “user” is any individual, entity, or organization that uses an apparatus 100. As a non-limiting example, user 128 may include an architect, structural engineer, and the like. Representative part model 120 may be received through user input, such and without limitations, by a user 128 inputting or uploading representative part model 120 into processor 104.

With continued reference to FIG. 1, in some embodiments, apparatus 100 may include a part database 132. As used in this disclosure, “part database” is a data structure configured to store data associated with a representative part model. As a non-limiting example, part database 132 may store representative part model 120, part feature 136, design reference 140, part progress class label 144, design problem 146, design solution 148, design guidance 150, user prompt 152, and the like. In one or more embodiments, part database 132 may include inputted or calculated information and datum related to a representative part model 120. In some embodiments, a datum history may be stored in part database 132. As a non-limiting example, the datum history may include real-time and/or previous inputted data related to representative part model 120. As a non-limiting example, part database 132 may include instructions from a user, who may be an expert user, a past user in embodiments disclosed herein, or the like, where the instructions may include examples of the data related to representative part model 120.

With continued reference to FIG. 1, in some embodiments, processor 104 may be communicatively connected with part database 132. For example, and without limitation, in some cases, part database 132 may be local to processor 104. In another example, and without limitation, part database 132 may be remote to processor 104 and communicative with processor 104 by way of one or more networks. The network may include, but is not limited to, a cloud network, a mesh network, and the like. By way of example, a “cloud-based” system can refer to a system which includes software and/or data which is stored, managed, and/or processed on a network of remote servers hosted in the “cloud,” e.g., via the Internet, rather than on local severs or personal computers. A “mesh network” as used in this disclosure is a local network topology in which the infrastructure processor connect directly, dynamically, and non-hierarchically to as many other computing devices as possible. A “network topology” as used in this disclosure is an arrangement of elements of a communication network. The network may use an immutable sequential listing to securely store part database 132. An “immutable sequential listing,” as used in this disclosure, is a data structure that places data entries in a fixed sequential arrangement, such as a temporal sequence of entries and/or blocks thereof, where the sequential arrangement, once established, cannot be altered or reordered. An immutable sequential listing may be, include and/or implement an immutable ledger, where data entries that have been posted to the immutable sequential listing cannot be altered.

With continued reference to FIG. 1, in some embodiments, part database 132 may be implemented, without limitation, as a relational database, a key-value retrieval database such as a NOSQL database, or any other format or structure for use as a database that a person skilled in the art would recognize as suitable upon review of the entirety of this disclosure. Database may alternatively or additionally be implemented using a distributed data storage protocol and/or data structure, such as a distributed hash table or the like. Database may include a plurality of data entries and/or records as described above. Data entries in a database may be flagged with or linked to one or more additional elements of information, which may be reflected in data entry cells and/or in linked tables such as tables related by one or more indices in a relational database. Persons skilled in the art, upon reviewing the entirety of this disclosure, will be aware of various ways in which data entries in a database may store, retrieve, organize, and/or reflect data and/or records as used herein, as well as categories and/or populations of data consistently with this disclosure.

With continued reference to FIG. 1, in some embodiments, processor 104 may receive representative part model 120 by extracting representative part model 120 from a print using a machine vision system 154. For the purposes of this disclosure, a “machine vision system” is a type of technology that enables a computing device to inspect, evaluate and identify still or moving images. For example, in some cases a machine vision system 154 may be used for world modeling or registration of objects within a space. In some cases, registration may include image processing, such as without limitation object recognition, feature detection, edge/corner detection, and the like. Non-limiting example of feature detection may include scale invariant feature transform (SIFT), Canny edge detection, Shi Tomasi corner detection, and the like. In some cases, a machine vision system 154 may operate image classification and segmentation models, such as without limitation by way of machine vision resource (e.g., OpenMV or TensorFlow Lite). A machine vision system 154 may detect markers, for example blob detection, object detection, face detection, and the like. In some cases, a machine vision system 154 may additionally perform image capture and/or video recording.

With continued reference to FIG. 1, in some cases, registration may include one or more transformations to orient a camera frame (or an image or video stream) relative a three-dimensional coordinate system; exemplary transformations include without limitation homography transforms and affine transforms. In an embodiment, registration of first frame to a coordinate system may be verified and/or corrected using object identification and/or computer vision, as described above. For instance, and without limitation, an initial registration to two dimensions, represented for instance as registration to the x and y coordinates, may be performed using a two-dimensional projection of points in three dimensions onto a first frame, however. A third dimension of registration, representing depth and/or a z axis, may be detected by comparison of two frames; for instance, where first frame includes a pair of frames captured using a pair of cameras (e.g., stereoscopic camera also referred to in this disclosure as stereo-camera), image recognition and/or edge detection software may be used to detect a pair of stereoscopic views of images of an object; two stereoscopic views may be compared to derive z-axis values of points on object permitting, for instance, derivation of further z-axis points within and/or around the object using interpolation. This may be repeated with multiple objects in field of view, including without limitation environmental features of interest identified by object classifier and/or indicated by an operator. In an embodiment, x and y axes may be chosen to span a plane common to two cameras used for stereoscopic image capturing and/or an xy plane of a first frame; a result, x and y translational components and ø may be pre-populated in translational and rotational matrices, for affine transformation of coordinates of object, also as described above. Initial x and y coordinates and/or guesses at transformational matrices may alternatively or additionally be performed between first frame and second frame, as described above. For each point of a plurality of points on object and/or edge and/or edges of object as described above, x and y coordinates of a first stereoscopic frame may be populated, with an initial estimate of z coordinates based, for instance, on assumptions about object, such as an assumption that ground is substantially parallel to an xy plane as selected above. Z coordinates, and/or x, y, and z coordinates, registered using image capturing and/or object identification processes as described above may then be compared to coordinates predicted using initial guess at transformation matrices; an error function may be computed using by comparing the two sets of points, and new x, y, and/or z coordinates, may be iteratively estimated and compared until the error function drops below a threshold level.

With continued reference to FIG. 1, in some cases, a machine vision system 154 may use at least an image classifier, or any classifier described throughout this disclosure. As a non-limiting example, a machine vision system 154 may use an image classifier, wherein the input is print or any two-dimensional format of representative part model 120, and through a classification algorithm, outputs representative part model 120 based on training data. Processor 104 and/or another device may generate a classifier using a classification algorithm, defined as a process whereby a computing device derives a classifier from training data. Classification may be performed using, without limitation, linear classifiers such as without limitation logistic regression and/or Bayes classifiers, nearest neighbor classifiers such as k-nearest neighbors classifiers, support vector machines, least squares support vector machines, fisher's linear discriminant, quadratic classifiers, decision trees, boosted trees, random forest classifiers, learning vector quantization, and/or neural network-based classifiers.

With continued reference to FIG. 1, in some cases, apparatus 100 may include an add-on software configured to be added to another software program. An “add-on” for the purposes of this disclosure is a feature allowing a device or a software to be added to an already existing device or software. The add-on may provide for enhanced features and/or added features. Apparatus 100 may be configured as an add-on for an existing design program wherein a user 128 may interact with apparatus without having to leave the current software program. As a non-limiting example, apparatus 100 may be configured as an add on for a design software such as solid works, wherein user 128 may interact with apparatus 100 within Solid works. The user 128 may receive design guidance problems and solutions within Solid works. Apparatus 100 may receive representative part model 120 in a format similar to the format that the model is being generated within the design software. Apparatus 100 may further provide design solutions 148, components 116 and the like in a similar format as the representative part model 120 was received. In some cases, processor 104 may receive representative model through an add-on feature of another program. For example, processor 104 may automatically receive representative part model 120 based on a user's interaction with the software. A user 128 may be building or designing a part wherein processor 104 may automatically detect the presence of a part or representative part model 120 and may receive the part or representative part model 120. In some cases, user 128 may interact with a feature within the software program to submit the part to processor.

With continued reference to FIG. 1, in some embodiments, processor 104 may retrieve semantic information of representative part model 120 from a print or two dimensional format of representative part model 120 using an optical character recognition (OCR). For the purposes of this disclosure, “optical character recognition” is a technology that enables the recognition and conversion of printed or written text into machine-encoded text. In some cases, processor 104 may be configured to recognize a keyword using the OCR to find semantic information of representative part model 120. As used in this disclosure, a “keyword” is an element of word or syntax used to identify and/or match elements to each other. In some cases, processor 104 may transcribe much or even substantially all print or two dimensional format of representative part model 120.

With continued reference to FIG. 1, in some embodiments, optical character recognition or optical character reader (OCR) may include automatic conversion of images of written (e.g., typed, handwritten or printed text) into machine-encoded text. In some cases, recognition of a keyword from a print or two dimensional format of representative part model 120 may include one or more processes, including without limitation optical character recognition (OCR), optical word recognition, intelligent character recognition, intelligent word recognition, and the like. In some cases, OCR may recognize written text, one glyph or character at a time. In some cases, optical word recognition may recognize written text, one word at a time, for example, for languages that use a space as a word divider. In some cases, intelligent character recognition (ICR) may recognize written text one glyph or character at a time, for instance by employing machine-learning processes. In some cases, intelligent word recognition (IWR) may recognize written text, one word at a time, for instance by employing machine-learning processes.

With continued reference to FIG. 1, in some cases, OCR may be an “offline” process, which analyses a static document or image frame. In some cases, handwriting movement analysis can be used as input to handwriting recognition. For example, instead of merely using shapes of glyphs and words, this technique may capture motions, such as the order in which segments are drawn, the direction, and the pattern of putting the pen down and lifting it. This additional information may make handwriting recognition more accurate. In some cases, this technology may be referred to as “online” character recognition, dynamic character recognition, real-time character recognition, and intelligent character recognition.

With continued reference to FIG. 1, in some cases, OCR processes may employ pre-processing of a print or two dimensional format of representative part model 120. Pre-processing process may include without limitation de-skew, de-speckle, binarization, line removal, layout analysis or “zoning,” line and word detection, script recognition, character isolation or “segmentation,” and normalization. In some cases, a de-skew process may include applying a transform (e.g., homography or affine transform) to a print or two dimensional format of representative part model 120 to align text. In some cases, a de-speckle process may include removing positive and negative spots and/or smoothing edges. In some cases, a binarization process may include converting an image from color or greyscale to black-and-white (i.e., a binary image). Binarization may be performed as a simple way of separating text (or any other desired image component) from a background of image component. In some cases, binarization may be required for example if an employed OCR algorithm only works on binary images. In some cases, a line removal process may include removal of non-glyph or non-character imagery (e.g., boxes and lines). In some cases, a layout analysis or “zoning” process may identify columns, paragraphs, captions, and the like as distinct blocks. In some cases, a line and word detection process may establish a baseline for word and character shapes and separate words, if necessary. In some cases, a script recognition process may, for example in multilingual documents, identify script allowing an appropriate OCR algorithm to be selected. In some cases, a character isolation or “segmentation” process may separate signal characters, for example character-based OCR algorithms. In some cases, a normalization process may normalize aspect ratio and/or scale of image component.

With continued reference to FIG. 1, in some embodiments an OCR process may include an OCR algorithm. Exemplary OCR algorithms include matrix matching process and/or feature extraction processes. Matrix matching may involve comparing an image to a stored glyph on a pixel-by-pixel basis. In some case, matrix matching may also be known as “pattern matching,” “pattern recognition,” and/or “image correlation.” Matrix matching may rely on an input glyph being correctly isolated from the rest of the image component. Matrix matching may also rely on a stored glyph being in a similar font and at a same scale as input glyph. Matrix matching may work best with typewritten text.

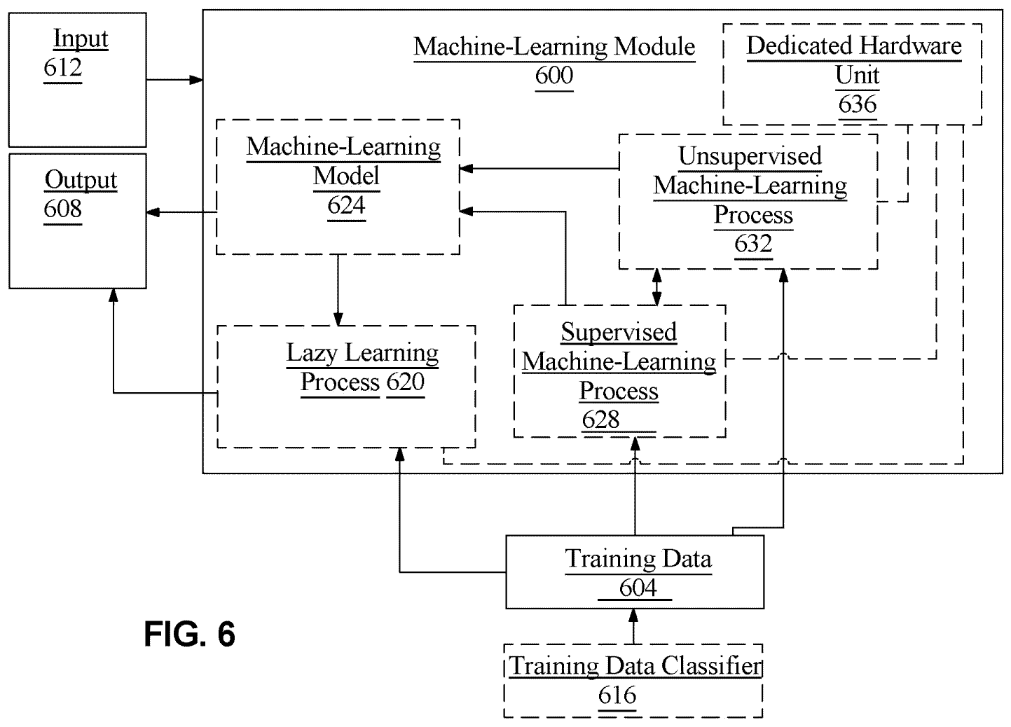

With continued reference to FIG. 1, in some embodiments, an OCR process may include a feature extraction process. In some cases, feature extraction may decompose a glyph into a feature. Exemplary non-limiting features may include corners, edges, lines, closed loops, line direction, line intersections, and the like. In some cases, feature extraction may reduce dimensionality of representation and may make the recognition process computationally more efficient. In some cases, extracted feature may be compared with an abstract vector-like representation of a character, which might reduce to one or more glyph prototypes. General techniques of feature detection in computer vision are applicable to this type of OCR. In some embodiments, machine-learning processes like nearest neighbor classifiers (e.g., k-nearest neighbors algorithm) may be used to compare image features with stored glyph features and choose a nearest match. OCR may employ any machine-learning process described in this disclosure, for example machine-learning processes described with reference to FIG. 6. Exemplary non-limiting OCR software may include Cuneiform and Tesseract. Cuneiform may include a multi-language, open-source optical character recognition system originally developed by Cognitive Technologies of Moscow, Russia. Tesseract may include free OCR software originally developed by Hewlett-Packard of Palo Alto, California, United States.

With continued reference to FIG. 1, in some cases, OCR may employ a two-pass approach to character recognition. A first pass may try to recognize a character. Each character that is satisfactory may be passed to an adaptive classifier as training data. The adaptive classifier then may get a chance to recognize characters more accurately as it further analyzes a print or two dimensional format of representative part model 120. Since the adaptive classifier may have learned something useful a little too late to recognize characters on the first pass, a second pass may be run over a print or two dimensional format of representative part model 120. Second pass may include adaptive recognition and use characters recognized with high confidence on the first pass to recognize better remaining characters on the second pass. In some cases, two-pass approach may be advantageous for unusual fonts or low-quality image components where visual verbal content may be distorted. Another exemplary OCR software tool may include OCRopus. OCRopus development is led by German Research Centre for Artificial Intelligence in Kaiserslautern, Germany. In some cases, OCR software may employ neural networks.

With continued reference to FIG. 1, in some cases, OCR may include post-processing. For example, OCR accuracy may be increased, in some cases, if output is constrained by a lexicon. A lexicon may include a list or set of words that are allowed to occur in a document. In some cases, a lexicon may include, for instance, all the words in the English language, or a more technical lexicon for a specific field. In some cases, an output stream may be a plain text stream or file of characters. In some cases, an OCR process may preserve an original layout of visual verbal content. In some cases, near-neighbor analysis can make use of co-occurrence frequencies to correct errors, by noting that certain words are often seen together. For example, “Washington, D.C.” is generally far more common in English than “Washington DOC.” In some cases, an OCR process may make us of a priori knowledge of grammar for a language being recognized. For example, grammar rules may be used to help determine if a word is likely to be a verb or a noun. Distance conceptualization may be employed for recognition and classification. For example, a Levenshtein distance algorithm may be used in OCR post-processing to further optimize results.

With continued reference to FIG. 1, apparatus 100 may further be configured to retrieve any other relevant data such as, and without limitation, View Type, Geometry Configuration, Building Assembly Types, Building Assembly Layers, and the like from user's design models/drawings to identify their design problem. In some cases, apparatus 100 may be configured to classify or categorize data using the original format that the representative part model 120 was received in. For example, processor 104 may receive representative part model in a STEP format wherein processor 104 may perform calculation and determinations on the file and produce a similar file.

With continued reference to FIG. 1, memory 108 contains instructions configuring processor 104 to determine at least a part feature 136 of representative part model 120. For the purposes of this disclosure, a “part feature” is a distinctive characteristic of a representative part model. As a non-limiting example, part feature 136 may include specific components or elements of representative part model 120, edge or geometric collision or connection between two or more components or elements in representative part model 120 where two or more building components or elements intersect or overlap. For example, and without limitation, part feature 136 may include a roof, curtain wall on ground, skylight ridge, collision or connection between curtain wall and a first floor of a building, and the like. In some embodiments, part feature 136 may include feature vectors that are numerical representations of characteristics of representative part model 120. In some embodiments, part feature 136 may be stored in part database 132. In some embodiments, processor 104 may retrieve part feature 136 from part database 132. In some embodiments, user may manually determine part feature 136 through user interface 156 of remote device 124. In some embodiments, processor 104 may determine part feature 136 using machine vision system 154 as described above.

With continued reference to FIG. 1, in some embodiments, processor 104 may determine part feature 136 using a feature machine-learning model 158. In some embodiments, processor 104 may be configured to generate feature training data. In a non-limiting example, feature training data may include correlations between exemplary representative part models and exemplary part features. In some embodiments, feature training data may be stored in part database 132. In some embodiments, feature training data may be received from one or more users, part database 132, external computing devices, and/or previous iterations of processing. As a non-limiting example, feature training data may include instructions from a user, who may be an expert user, a past user in embodiments disclosed herein, or the like, which may be stored in memory and/or stored in part database 132, where the instructions may include labeling of training examples. In some embodiments, feature training data may be updated iteratively on a feedback loop. As a non-limiting example, processor 104 may update feature training data iteratively through a feedback loop as a function of representative part model 120, part feature 136, output of machine vision system 154, or the like. In some embodiments, processor 104 may be configured to generate feature machine-learning model. In a non-limiting example, generating feature machine-learning model may include training, retraining, or fine-tuning feature machine-learning model using feature training data or updated feature training data. In some embodiments, processor 104 may be configured to determine part feature 136 using feature machine-learning model 158 (e.g., trained or updated feature machine-learning model). In some embodiments, generating training data and training machine-learning models may be simultaneous.

With continued reference to FIG. 1, in some cases, processor 104 may be configured to segment representative part model 120 into one or more building parts 160 as a function of at least a part feature 136. For the purposes of this disclosure, a “building part” is a portion of a representative part model that has any distinctive characteristic. As a non-limiting example, building part 160 may include a classified element within representative part model 120. In some cases, processor 104 may provide data on each segment such as parts that may be purchased, sizing, and any other information. In some cases, graphical user interface (GUI) of user interface 156 of remote device 124 may be configured to display visual element corresponding to each classified element (e.g., building part 160) wherein a user may view each visual element. In some cases, GUI may allow for a user to select a particular region (e.g., building part 160) of representative part model 120 that is displayed in order for a user to search through and select similar physical parts (e.g., component 116) corresponding to classified elements within representative part model 120. In some cases, user 128 may select a physical part corresponding to a classified element in representative part model 120 wherein processor 104 may generate an updated representative part model as a function of the selection. For example, selection of a particular physical product may create an updated representative part model having the design or features of the product. In some cases, user 128 may select a particular physical product associated with a classified element or segment based on user's needs. This may include needs based on aesthetics, performance and the like. In some cases, processor 104 may provide similar physical parts that are associated with the classified element. In some cases, processor 104 may be configured to segment representative part model 120 into one or more building parts 160 using a machine-learning model and/or any computing algorithm as described in this disclosure.

With continued reference to FIG. 1, memory 108 contains instructions configuring processor 104 to categorize representative part model 120 to a part progress class label 144 that defines a region class 162 and a design progress state 164 using a first machine-learning module 166. For the purposes of this disclosure, a “part progress class label” is an identifier that describes a region class and design progress state of a representative part model or building part. In some embodiments, processor 104 may categorize representative part model 120 or building part 160 to part progress class label 144 by combining region class 162 and design progress state 164 determined for representative part model 120 or building part 160. For example, and without limitation, part progress class label 144 may include ‘Initial Facade Section’ that indicates a representative part model 120 that has a design progress state 164 as ‘Initial’ and region class 162 as ‘Facade.’ For example, and without limitation, part progress class label 144 may include ‘In Progress Curtain Wall to Foundation Detail Section’ that indicates a building part 160 (e.g., ‘Detail Section’) of representative part model 120 that has a design progress state 164 as ‘In Progress’ and region class 162 as ‘Curtain Wall to Foundation.’ In some embodiments, part progress class label 144 may be stored in part database 132. In some embodiments, processor 104 may retrieve part progress class label 144 from part database 132. In some embodiments, user 128 may manually determine part progress class label 144.

With continued reference to FIG. 1, categorizing representative part model 120 includes determining region class 162 of representative part model 120 as a function of a design reference 140. A “region class” for the purposes of this disclosure is an identifier that describes a representative part model. For example, a region class 162 may include walls, roofs, doors and/or any other components used in construction. In some cases, region classes 162 may include any components that may be added to a large part, such as and without limitations, doors, walls, heating systems, cooling systems, and the like. For example, and without limitation, region class 162 may include ‘curtain wall to foundation,’ ‘rainscreen parapet,’ ‘skylight ridge,’ ‘sloped glazing assembly curb,’ ‘curtain wall and first floor,’ ‘soffit at curtain wall,’ ‘curtain wall parapet at roof,’ and the like. In some embodiments, processor 104 determines region class 162 of representative part model 120. As a non-limiting example, region class 162 may include ‘facade’ for representative part model 120 related to a facade. As a non-limiting example, region class 162 may include ‘roof’ for representative part model 120 related to a roof. In some embodiments, processor 104 may determine region class 162 of building part 160 of representative part model 120. As a non-limiting example, region class 162 may include ‘curtain wall parapet at roof’ for building part 160 related to a curtain wall parapet of representative part model 120 related to a roof. In some embodiments, region class 162 may be stored in part database 132. In some embodiments, processor 104 may retrieve region class 162 from part database 132. In some embodiments, user 128 may manually determine region class 162.

With continued reference to FIG. 1, in some cases, processor 104 may classify elements of representative part model 120 to a region class 162 in order to determine the particular elements within the representative part model 120. For example, classification may include determining that a door, or a black exterior wall region exists. Processor 104 may classify elements (e.g., part feature 136 or building part 160) of representative part model 120 to at least one region class 162, wherein each class labeling may be determinative that a particular element exists. For example, a label indicating that an element is classified to a door class may be determinative that a door is located within representative part model 120. In some cases, each classification may be indicative that a particular element exists. For example, multiple labels associated with multiple region classes may be indicative that particular elements exists within representative part model 120. In some cases, processor 104 may classify elements of representative part model 120 such that a user may be able to determine what physical parts are needed for the manufacturing and/or building of representative part model 120. In some cases, processor 104 may identify elements within representative part model 120 by classifying elements within representative part model and provide visual description to a user of each classified element. In some cases, each classified element may contain information such as where to purchase, the part, similar parts and the like.

With continued reference to FIG. 1, in some embodiments, processor 104 may determine region class 162 using a machine-learning model trained with training data. Training data may include a database of prints of representative part models and their corresponding building components. For example, training data may include a hatch pattern that is associated with various materials, such as a cross hatch that is associated with alloys. In an embodiment, machine-learning model may identify a print of a section of the representative part model 120 as brick veneer with concrete masonry unit wall back up. In another embodiment, machine-learning model may identify a print of the representative part model 120 as a rainscreen with cold-formed metal framing backup wall-to-soffit design.

With continued reference to FIG. 1, for the purposes of this disclosure, a “design reference” is a visual representation of a part to be manufactured or built that can be used as a reference or benchmark. In some embodiments, design reference 140 may be consistent with a representative part model 120 that has design progress state 164 as ‘Completed.’ Design reference 140 includes design standards 168. For the purposes of this disclosure, a “design standard” is information related to a representative part model that provides standardized guidelines or specifications. As a non-limiting example, design standard 168 may include regulatory compliance, structural criteria, dimensional requirement, material specification, building codes and regulations, energy codes and regulations, and the like. In some embodiments, user 128 may manually determine or input design reference 140 or design standard 168. In some embodiments, design reference 140 or design standard 168 may be stored in part database 132.

With continued reference to FIG. 1, processor 104 is configured to retrieve design reference 140 from part database 132. In some embodiments, design reference 140 stored in part database 132 may has its region class and once design reference 140 is retrieved from part database 132 for a specific representative part model 120 or building part 160, the region class of design reference 140 may be determined as region class 162 of representative part model 120 or building part 160. Processor 104 is configured to query design reference 140 from part database 132 as a function of part feature 136. As a non-limiting example, processor 104 may query design reference 140 from part database 132 that has features that are similar to or same as part features 136 of representative part model 120. In some embodiments, processor 104 may query design reference 140 from part database 132 using similarity metrics that quantifies the degree of resemblance between representative part model 120 and design reference 140 stored in part database 132. In some embodiments, processor 104 may generate similarity metrics as a function of feature vectors. As a non-limiting example, similarity metrics may include Euclidean distance, cosine similarity, and Hamming distance. Euclidean distance measures the straight-line distance between two points in a multi-dimensional space, providing a direct measure of dissimilarity where smaller distances indicate greater similarity. Cosine similarity measures the cosine of the angle between two vectors, effectively assessing the orientation rather than the magnitude, making it robust against differences in lighting and scale. Hamming distance can be used for binary feature vectors, counting the number of differing bits between two vectors, thus providing a simple and effective measure for binary data. In some embodiments, processor 104 may rank design reference 140 based on their similarity to representative part model 120 using similarity metrics, enabling efficient retrieval of the most relevant matches. In some embodiments, once the similarity metrics have quantified the resemblance between representative part model 120 and design reference 140, processor 104 may implement nearest neighbor search techniques. Nearest neighbor search identifies the points in a dataset that are closest to a given query point based on a specified distance metric. In k-Nearest Neighbors (k-NN) algorithm, ‘k’ represents the number of closest points to be retrieved. This algorithm can scan the entire dataset to find the ‘k’ most similar images, making it highly accurate but computationally intensive for large datasets. Approximate nearest neighbors algorithms such as KD-Tree and Locality-Sensitive Hashing (LSH) may be employed. KD-Tree organizes data points into a tree structure based on their spatial coordinates, significantly speeding up search times by reducing the number of points to be considered. LSH hashes data points into buckets such that similar points are more likely to be placed in the same bucket, allowing for quick retrieval of approximate nearest neighbors. In some embodiments, processor 104 may compare feature vector of representative part model 120 or building part 160 with vectors of design reference 140 in part database 132 using similarity metrics and nearest neighbor search techniques. In some embodiments, processor 104 may rank design reference 140 based on their similarity scores relative to representative part model 120 or building part 160, retrieving the top matches.

With continued reference to FIG. 1, categorizing representative part model 120 includes determining design progress state 164 of representative part model 120 as a function of design reference 140. For the purposes of this disclosure, a “design progress state” is a phase within an overall design process of a representative part model 120, indicating a level of completion. As a non-limiting example, design progress state 164 may include characteristic value; for instance, ‘Initial,’ ‘In Progress,’ ‘Completed,’ and the like. As another non-limiting example, design progress state 164 may include numerical value; for instance, ‘10%,’ ‘60%,’ ‘100%,’ and the like in a range of 0-100%, where 0% indicates a representative part model 120 is not designed at all and 100% indicates a representative part model 120 is completely designed. In some embodiments, design progress state 164 may be stored in part database 132. In some embodiments, processor 104 may retrieve design progress state 164 from part database 132. In some embodiments, user 128 may manually determine or input design progress state 164.

With continued reference to FIG. 1, in some embodiments, processor 104 may be configured to generate first training data 170. For the purposes of this disclosure, “first training data” is data containing correlations that a machine-learning process may use to model relationships between a design reference and a design progress state. In a non-limiting example, first training data 170 may include correlations between exemplary design references, exemplary representative part models and/or exemplary building parts and exemplary design progress state. In some embodiments, first training data 170 may be stored in part database 132. In some embodiments, first training data 170 may be received from one or more users, part database 132, external computing devices, and/or previous iterations of processing. As a non-limiting example, first training data 170 may include instructions from a user, who may be an expert user, a past user in embodiments disclosed herein, or the like, which may be stored in memory and/or stored in part database 132, where the instructions may include labeling of training examples. In some embodiments, first training data 170 may be updated iteratively on a feedback loop. As a non-limiting example, processor 104 may update first training data 170 iteratively through a feedback loop as a function of part feature 136, output of feature machine-learning model 158, representative part model 120, building part 160, output of machine vision system 154, design reference 140, region class 162, and the like. In some embodiments, processor 104 may be configured to generate a first machine-learning module 166. For the purposes of this disclosure, a “first machine-learning module” is a machine-learning model that determines a design progress state for a representative part model or building part. In a non-limiting example, generating first machine-learning module 166 may include training, retraining, or fine-tuning first machine-learning module 166 using first training data 170 or updated first training data 170. In some embodiments, processor 104 may be configured to determine region class 162 using first machine-learning module 166 (i.e. trained or updated first machine-learning module 166). In some embodiments, first machine-learning module 166 may compare representative part model 120 or building part 160 with design reference 140, which is a completed design of a part, determine how close representative part model 120 or building part 160 to design reference 140 and determine design progress state 164 of representative part model 120 or building part 160. In some embodiments, generating training data and training machine-learning models may be simultaneous.

With continued reference to FIG. 1, representative part model 120 may be classified to a design class. A “design class” for the purposes of this disclosure is a grouping of representative part model 120 based on particular design parameter. Design class may include classes such as, and without limitation, construction types, climate zones, use and occupancy types of the like. In some cases representative part model 120 may be classified to one or more design classes such a particular construction type, a particular climate zone and the like. In some cases, representative part model may include data indicating a particular class it belongs to wherein processor 104 may label representative part model 120 with the appropriate class. In some cases classifying representative part model 120 may include using a classifier machine-learning model. Using the classifier machine-learning model may include receiving training data. Training data may include a plurality of representative part models correlated to a plurality of design classes. In an embodiment, training data may indicate that a particular representative part model 120 may be associated with a particular class. In some cases, training data may be received from a user, a third party, database, external computing devices, previous iterations of the function and/or the like. In some embodiments, training data may be stored in a database. In some embodiments, training data may be retrieved from a database. In some embodiments, representative part model 120 and the correlated design class may be stored in a database and used as training data for future iterations. Similarly, training data may be created from previous iterations wherein a previous representative part model 120 and correlated design class was received and stored on a database. Classifying representative part model 120 may further include training a machine-learning model as a function of the training data and classifying representative part model 120 as a function of the machine-learning model. In some embodiments, outputs of the machine-learning model may be used to train the training data.

With continued reference to FIG. 1, processor 104 is configured to determine a design problem 146 of representative part model 120. For the purposes of this disclosure, a “design problem” is a portion of a representative part model or building part that needs to be fixed or improved. In some embodiments, processor 104 may be configured to determine a design problem 146 of building part 160. In some embodiments, processor 104 may determine design problem 146 using a problem machine-learning model 172. Problem machine-learning model 172 may be a classifier, as discussed below. In some cases, design problem 146 may be an individual label within a grouping of labels wherein representative part model 120 is classified and/or categorized to a particular design problem. In some cases, representative part model 120 may be classified to a particular class and/or category wherein the classification of a particular class may indicate a particular design problem 146. For example, representative part model 120 may be categorized and/or classified to a particular design problem 146 that may indicate that representative part model 120 requires a particular solution. In some cases, representative part model 120 may be categorized to more than one design problems wherein each design problem 146 may indicate a particular issue that requires an associated solution. In some cases representative part model 120 may be categorized using a classifier. A design problem 146 may be areas in representative part model 120 that needs more details and refinement. Design problem 146 may also include determining physical properties of various materials. A design problem 146 may further include structural issues, weak points, points that may be prone to damage, points that may be prone to bending and the like. In some cases, design problem 146 may include structural weak points of a part, wherein the manufacturing of said part may result in a product prone to damage. In some cases, design problem 146 may include the maximum loads, stress, tensile strength, and the like for a particular part. This information may be used to determine the current strength of a particular part and compare it to regulations within a given geographic area. For example, design problem 146 may indicate that a particular model contains a maximum strength that is less than the required strength for such a model with respect to governmental regulations. Another design problem 146 may include designing to a manufacturer's standards. In an embodiment, design problems arise after the initial design of a building, during design development and construction documentation phases. During these phases, the representative part model 120 may be transformed from a basic design to include details such as a structural system, heating and cooling systems, lighting systems, written specifications covering all materials used in the building, methods of construction, or the like. In some embodiments, design problem 146 may be stored in part database 132. In some embodiments, processor 104 may retrieve design problem 146 from part database 132. In some embodiments, user 128 may manually determine design problem 146.

With continued reference to FIG. 1, in an embodiment, problem machine-learning model 172 may identify a potential problem in representative part model 120 during a building assembly design process that needs to be resolved to complete the design. For example, problem machine-learning model 172 may identify various lines as different building components such as a wall or a window or brick veneer. Problem machine-learning model 172 may be supervised and may be trained with problem training data. In some cases, training data may include a plurality of representative part models correlated to a plurality of design problems. In an embodiment, a particular representative part model may indicate a particular design problem. In some cases, a particular representative part model may be categorized to a particular design problem.

With continued reference to FIG. 1, processor 104 is configured to generate a design solution 148 using a second machine-learning module 174, as a function of at least a design problem 146. For the purposes of this disclosure, a “design solution” is a method that address a design problem of a representative part model or building part. Design solution 148 may include design guidance based on design problem 146 that help complete the overall representative part model 120. For the purposes of this disclosure, a “design guidance” is a guide that provides a user a next step to complete designing a representative device. Design solution 148 may be presented in a visual format, such as a visual drawing, or the like. For example, second machine-learning module 174 may identify a need for a necessary air vapor barrier when using continuous thermal insulation. Second machine-learning module 174 may also identify that the air vapor barrier may need sheathing to support it and ventilation holes so ventilate it. In some cases, second machine-learning module 174 may identify that a particular component within representative part model 120 may need to be required of a particular material. This requirement may be due to structural issues, environmental issues, safety issues and the like. In some cases, second machine-learning module 174 may identify that a particular component may need to be resized due to structural, environmental and/or safety issues. In some cases, design solution 148 may contain more than one solution to help complete the overall representative part model 120. In some cases, an individual solution within design solution 148 may be associated with an individual design problem 146. Design problem 146 may contain more than one problem wherein design solution 148 contains multiple solutions wherein each solution within design solution 148 is associated with each problem within design problem 146. For example, a particular problem within design problem 146 may have a corresponding solution within design solution 148. In an embodiment, a user 128 may be guided through these design choices. In some embodiments, design solution 148 may be stored in part database 132. In some embodiments, processor 104 may retrieve design solution 148 from part database 132. In some embodiments, user 128 may manually determine design solution 148.

With continued reference to FIG. 1, in some embodiments, second machine-learning module 174 may be supervised. Second machine-learning module 174 may be trained using second training data 176. Second training data 176 may include previously identified design problems on representative part models. In some cases, second training data 176 may further include a plurality of design problems correlated to a plurality of design solutions. In an embodiment, a particular design problem may be correlated to a particular solution. Second training data 176 may be user inputted such that a user 128 may input categorized representative part model 120 and output key design points based on the categorized representative part model 120. In some embodiments, second training data 176 may be stored in part database 132. In some embodiments, second training data 176 may be received from one or more users, part database 132, external computing devices, and/or previous iterations of processing. As a non-limiting example, second training data 176 may include instructions from a user, who may be an expert user, a past user in embodiments disclosed herein, or the like, which may be stored in memory and/or stored in part database 132, where the instructions may include labeling of training examples. In some embodiments, second training data 176 may be updated iteratively on a feedback loop. As a non-limiting example, processor 104 may update second training data 176 iteratively through a feedback loop as a function of part feature 136, output of feature machine-learning model 158, representative part model 120, building part 160, output of machine vision system 154, design reference 140, region class 162, output of first machine-learning module 166, and the like. In some embodiments, processor 104 may train second machine-learning module 174 using second training data 176. Second machine-learning module 174 may include a generative adversarial network (GAN) which may process training data. As used herein, a “generative adversarial network” is an unsupervised learning task in machine-learning that involves automatically discovering and learning the regularities or patterns in input data in such a way that the model can be used to generate or output new examples that plausibly could have been drawn from the original dataset. In some cases, training data may be generated, by a user, 3^{rd} party or the like. In some cases, training data may be generated based on previous iterations of the processing.

With continued reference to FIG. 1, any training data described in this disclosure may be generated by a 3^{rd} party such as a consulting firm, a 3^{rd} party, a profession in the design and/or building fields and the like. In some cases, apparatus 100 may include a plurality of training data wherein each user and/or 3^{rd} party may create their own training data. For example, a particular consulting firm may generate their own training data comprising a plurality of inputs correlated to a plurality of outputs, wherein training data may indicate a particular output or a particular design solution 148. In some cases, differing training data may provide different outputs such as differing visual designs, differing components (e.g. such as those provided only by the consulting firm) and the like. In some cases, a user 128 may select from a plurality of training data to be used for computing wherein each training data may provide for a particular solution, problem, component and the like. In some cases, consulting firms and/or 3^{rd} parties may provide their own outputs wherein users 128 may interact with the consulting firms and reach out for feedback and advice. In some cases the plurality of training data may be used to set particular requirements amongst a company or an entity. For example, a specific company or business may have particular design problem 146 and/or design solution 148 that may need to be addressed whereas another entity may not. Training data may differ wherein each set of training data may contain a focus on a differing particular area. In some cases a particular entity may have requirements for completing and/or detailing a particular set of models whereas another entity may not.

With continued reference to FIG. 1, processor 104 may help complete representative part model 120 using design solution 148. In an embodiment, processor 104 may use BIM integrated objects that represent key design points that may need to be added to the representative part model 120. In an embodiment, BIM integrated objects may include various lines that represent different building components. For example, a user 128 may be able to click and drop an air vapor barrier that is represented by dotted lines of different lengths on to the representative part model 120. BIM integrated objects may be presented as a list to user 128 that may click and drop selected objects directly onto representative part model 120. A user 128 may select to add an air vapor barrier because of the design guidance and/or design solution 148 provided by the machine-learning modules discussed above. This click and drop feature may save time and labor during the design development and construction documentation phases of the design process. In some cases, processor 104 may produce at least one BIM integrated object as a function of the different building components wherein each BIM integrated object is a visual representation of a component such as key lines and the like. In some cases, producing the BIM object includes receiving a BIM object associated with the component. In some cases, a user may select a particular component wherein selection of a particular component may result in the production of the BIM integrated object by processor 104. In some cases, processor 104 may provide a plurality of BIM integrated objects that are each correlated to the components. User 128 may view differing BIM integrated objects that are correlated to components with different manufacturers. In some cases, 3^{rd} parties may upload a plurality of BIM integrated objects that are associated with components wherein processor may use the plurality of BIM integrated objects to provide to a user. In some cases, BIM integrated objects may be received from a third party. In some cases, BIM integrated objects may be received by a 3^{rd} party and validated by an operator to ensure its accuracy.

With continued reference to FIG. 1, processor 104 may recommend at least a component 116 from component database 112 based on design solution 148 and the design problem 146. For the purposes of this disclosure, a “component” is an element or part of an architectural structure. In an embodiment, problem machine-learning model 172 or first machine-learning module 166 may recognize specific materials on representative part model 120 and second machine-learning module 174 may recognize specific components 116 needed for representative part model 120. Processor 104 may pull components 116 from component database 112 that relate to representative part model 120. In an embodiment, processor 104 may tailor specific products from various manufacturers for a user 128 to consider and/or select for their design project. For example, using the various machine-learning modules, processor 104 may recognize that user 128 is designing a wall to soffit detail with metal panels. Processor 104 may recommend an ALUCOBOND® panel provided by ALUCOBOND®, of Benton Kentucky, to be used as a material choice for a metal panel. In selecting a specific material from a manufacturer, processor 104 may also provide BIM integrated objects associated with the specific material to be added to representative part model 120. For example, processor 104 may recommend an addition of an ALUCOBOND® Clip-Double if the user 128 were to use an ALCOBOND® metal panel. In some cases, determining the plurality of components 116 may include determining as a function of classifying representative part model 120 to a design class. Components 116 may be categorized to design classes wherein processor 104 may select on those components 116 that pertain to a similar class as representative part model 120.

With continued reference to FIG. 1, in some embodiments, processor 104 may determine component 116 as a function of an analysis of user's interaction with displayed components 116 or displayed representative part model 120 or part feature 136 on remote device 124 or analysis of user's preference for component 116. In a non-limiting example, user may interact or manipulate with representative part model 120 or part feature 136 displayed on remote device 124 by hovering around the part feature 136 or clicking the part feature 136 of representative part model 120 and upon receiving such interaction or manipulation from the user, processor 104 may determine component 116 based on the interaction. For example, and without limitation, processor 104 may determine component 116 that is related to part feature 136 or representative part model 120 that is selected by a user. In another non-limiting example, processor 104 may provide information or metadata of component 116, drawing references, and the like to the user based on the user's interaction. For instance, processor 104 may retrieve information or metadata of component 116, drawing references, and the like from a database or manufacturer may manually input into processor 104. In some embodiments, user's preference for component 116 may include a level of affordability, availability, price, specific types of components 116, specific materials of components 116, and the like of component 116. For example, and without limitation, user's preference for component 116 may include preference for component 116 may include affordability with a weight of 5, availability with a weight of 3 and price with a weight of 2. For example, and without limitation, user's preference for component 116 may include components 116 that only has material of metal. In a non-limiting example, processor 104 may determine component 116 that meets user's preference for component 116. This may be done manually by a user 128 or processor 104 may use a machine-learning process or multi-objective optimization model to determine component 116 that conforms user's requirements or preferences. In a non-liming illustrative example, when a user selects a part feature 136 and specifies that the user prefers the components 116 with specific manufacturer, processor 104 may determine components 116 that are from the specific manufacturer and retrieve information, drawing reference, and the like related to the components 116 that are from the specific manufacturer, then display the components 116 and the information to the user.

With continued reference to FIG. 1, in some embodiments, processor 104 may be configured to determine at least a physical and optimal parameter (POP) of design reference 140. As a non-limiting example, POP may include camera parameters, three dimensional (3D) depth, scale factor, light conditions of each pixel, and the like. In some embodiments, processor 104 may segment design reference 140 into a plurality of reference segments as a function of POP. This may be done manually by a user 128 or processor 104 may segment design reference 140 through the use of machine-learning module. Design reference 140 and/or plurality of reference segments may be displayed to user 128 on remote device 124 and user 128 may select one reference segment from plurality of displayed reference segments. This selection of reference segment may be analyzed as user's preference for component 116 may be analyzed. Once component 116 that are determined based on user's selection of design reference 140 or user's preference for component 116, processor 104 may determine a plurality of components 116 for user 128. When user 128 selects one component 116 from the plurality of components 116, processor 104 may determine POP of the selected component 116 that is similar to reference segment. The POP of the selected component 116 may be mapped and displayed to user 128. In a non-limiting example, user 128 may use this as a base of design for representative part model 120. In another non-limiting example, processor 104 may generate another set of components 116 that has aesthetic or visual similarity or performance similarity to the selected component 116 and displayed the set to user 128.

With continued reference to FIG. 1, in some embodiments, processor 104 may generate a design assist datum 178 as a function of design problem 146 and design solution 148 and generate a user interface 156 displaying design assist datum 178 on remote device 124. For the purposes of this disclosure, a “design assist datum” is a data element that prompts a user related to a design problem or a design solution. As a non-limiting example, design assist datum 178 may include a reminder or notification. For example, and without limitation, design assist datum 178 may remind a user 128 related to design problem 146 detected from representative part model 120 and design solution 148 generated to resolve design problem 146. In some embodiments, design assist datum 178 may include design solution 148, design problem 146, design guidance 150, and the like. In some embodiments, processor 104 may generate design assist datum 178 using a large language model 180 as described below. In some embodiments, user 128 may manually generate design assist datum 178.

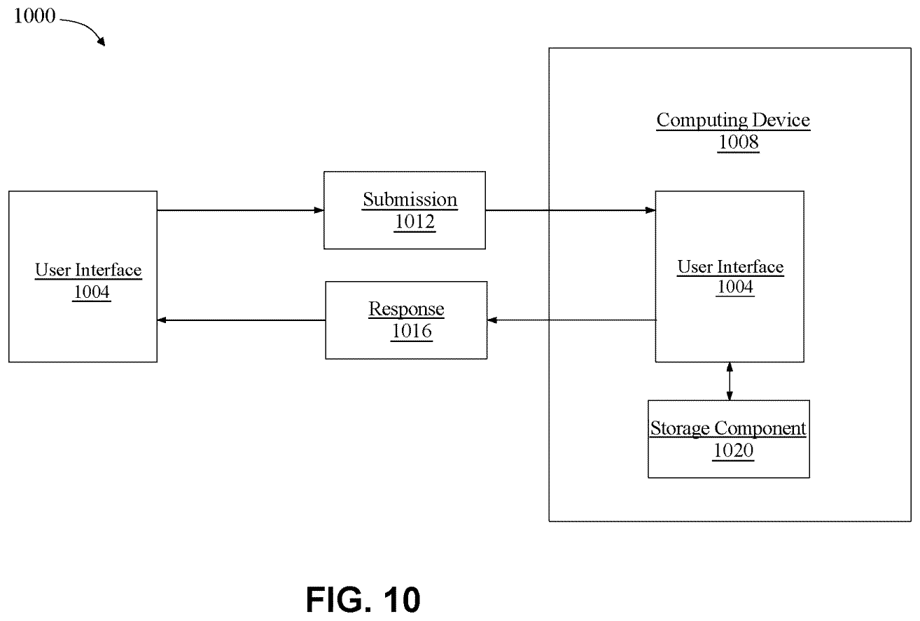

With continued reference to FIG. 1, in some embodiments, processor 104 may receive a user query 182 related to displayed representative part model 120 with part progress class label 144, design problem 146, and design solution 148 from remote device 124, generate a user prompt 152 as a function of user query 182 and generate user interface 156 displaying user prompt 152 on remote device 124. For the purposes of this disclosure, a “user query” is a question or request for information submitted by a user to a processor. As a non-limiting example, user query 182 may include a question related to representative part model 120, design problem 146, design solution 148, component 116, and the like and processor 104 may generate user prompt 152 as a function of user query 182. As another non-limiting example, user query 182 may include a request for information related to representative part model 120, design problem 146, design solution 148, component 116, and the like and processor 104 may generate user prompt 152, design problem 146, design solution 148, or component 116 as a function of user query 182. For the purposes of this disclosure, a “user prompt” is a response generated for a user query. As a non-limiting example, user prompt 152 may include text, image, video, icon, and the like. In some embodiments, user prompt 152 may be stored in part database 132. In some embodiments, processor 104 may retrieve user prompt 152 from part database 132. In some embodiments, user 128 may manually determine user prompt 152. In some embodiments, processor 104 may implement a chatbot and may receive user query 182 and transmit user prompt 152 through chatbot. For the purposes of this disclosure, “chatbot” is an artificial intelligence (AI) program designed to simulate human conversation or interaction through text, voice-based or image-based communication. The chatbot disclosed herein is further described with respect to FIG. 10.

With continued reference to FIG. 1, in some embodiments, generating user prompt 152 may include generating language training data 184, wherein language training data 184 may include exemplary user queries correlated to exemplary user prompts, wherein language training data 184 may be extracted from part database 132, training a large language model (LLM) 180 using language training data 184 and generating user prompt 152 as a function of user prompt 152 using trained large language model 180. A “large language model,” as used herein, is a deep learning data structure that can recognize, summarize, translate, predict and/or generate text and other content based on knowledge gained from massive datasets. Large language models 180 may be trained on large sets of data. Language training data 184 may be drawn from diverse sets of data such as, as non-limiting examples, articles, design references, textbooks, case studies, design blogs, design communities, educational website, design libraries and repositories, and the like. In some embodiments, language training data 184 may include a variety of subject matters, such as, as nonlimiting examples, architecture, graphical design, web design, building, building codes and regulations, energy codes and regulations, and the like. In some embodiments, language training data 184 of an LLM 180 may include information from one or more public or private databases (e.g., part database 132). As a non-limiting example, language training data 184 may include databases associated with representative part model 120. In some embodiments, language training data 184 may include portions of documents associated with representative part model 120 correlated to examples of outputs. In an embodiment, an LLM 180 may include one or more architectures based on capability requirements of an LLM 180. Exemplary architectures may include, without limitation, GPT (Generative Pretrained Transformer), BERT (Bidirectional Encoder Representations from Transformers), T5 (Text-To-Text Transfer Transformer), and the like. Architecture choice may depend on a needed capability such generative, contextual, or other specific capabilities.

With continued reference to FIG. 1, in some embodiments, an LLM 180 may be generally trained. As used in this disclosure, a “generally trained” LLM is an LLM that is trained on a general language training data comprising a variety of subject matters, data sets, and fields. In some embodiments, an LLM 180 may be initially generally trained. Additionally, or alternatively, an LLM 180 may be specifically trained. As used in this disclosure, a “specifically trained” LLM is an LLM that is trained on a specific language training data, wherein the specific language training data includes data including specific correlations for the LLM to learn. As a non-limiting example, an LLM 180 may be generally trained on a general language training data, then specifically trained on a specific language training data. As a non-limiting example, general language training data may include information related to representative part model 120 from internet using a web crawler, and specific language training data may include information related to representative part model 120 from part database 132 (e.g., design reference 140). In an embodiment, specific training of an LLM 180 may be performed using a supervised machine learning process. In some embodiments, generally training an LLM 180 may be performed using an unsupervised machine learning process. As a non-limiting example, specific language training data 184 may include information from a database (e.g., part database 132 or component database 112). As a non-limiting example, specific language training data 184 may include text related to representative part model 120 (e.g., semantic information, part feature 136, design reference 140, design standard, design problem 146, design solution 148, component 116, design guidance 150, and the like) correlated to examples of outputs. In an embodiment, training one or more machine learning models may include setting the parameters of the one or more models (weights and biases) either randomly or using a pretrained model. Generally training one or more machine learning models on a large corpus of text data can provide a starting point for fine-tuning on a specific task. A model such as an LLM 180 may learn by adjusting its parameters during the training process to minimize a defined loss function, which measures the difference between predicted outputs and ground truth. Once a model has been generally trained, the model may then be specifically trained to fine-tune the pretrained model on task-specific data to adapt it to the target task. Fine-tuning may involve training a model with task-specific training data, adjusting the model's weights to optimize performance for the particular task. In some cases, this may include optimizing the model's performance by fine-tuning hyperparameters such as learning rate, batch size, and regularization. Hyperparameter tuning may help in achieving the best performance and convergence during training. In an embodiment, fine-tuning a pretrained model such as an LLM 180 may include fine-tuning the pretrained model using Low-Rank Adaptation (LoRA). As used in this disclosure, “Low-Rank Adaptation” is a training technique for large language models that modifies a subset of parameters in the model. Low-Rank Adaptation may be configured to make the training process more computationally efficient by avoiding a need to train an entire model from scratch. In an exemplary embodiment, a subset of parameters that are updated may include parameters that are associated with a specific task or domain.

With continued reference to FIG. 1, in some embodiments an LLM 180 may include and/or be produced using Generative Pretrained Transformer (GPT), GPT-2, GPT-3, GPT-4, and the like. GPT, GPT-2, GPT-3, GPT-3.5, and GPT-4 are products of Open AI Inc., of San Francisco, CA. An LLM 180 may include a text prediction based algorithm configured to receive an article and apply a probability distribution to the words already typed in a sentence to work out the most likely word to come next in augmented articles. For example, if some words that have already been typed are “Continuous”, then it may be highly likely that the word “insulation” will come next. An LLM 180 may output such predictions by ranking words by likelihood or a prompt parameter. For the example given above, an LLM 180 may score “insulation” as the most likely, “air” as the next most likely, “membrane” next, and the like. An LLM 180 may include an encoder component and a decoder component.

With continued reference to FIG. 1, an LLM 180 may include a transformer architecture. In some embodiments, encoder component of an LLM 180 may include transformer architecture. A “transformer architecture,” for the purposes of this disclosure is a neural network architecture that uses self-attention and positional encoding. Transformer architecture may be designed to process sequential input data, such as natural language, with applications towards tasks such as translation and text summarization. Transformer architecture may process the entire input all at once. “Positional encoding,” for the purposes of this disclosure, refers to a data processing technique that encodes the location or position of an entity in a sequence. In some embodiments, each position in the sequence may be assigned a unique representation. In some embodiments, positional encoding may include mapping each position in the sequence to a position vector. In some embodiments, trigonometric functions, such as sine and cosine, may be used to determine the values in the position vector. In some embodiments, position vectors for a plurality of positions in a sequence may be assembled into a position matrix, wherein each row of position matrix may represent a position in the sequence.

With continued reference to FIG. 1, an LLM 180 and/or transformer architecture may include an attention mechanism. An “attention mechanism,” as used herein, is a part of a neural architecture that enables a system to dynamically quantify the relevant features of the input data. In the case of natural language processing, input data may be a sequence of textual elements. It may be applied directly to the raw input or to its higher-level representation.

With continued reference to FIG. 1, attention mechanism may represent an improvement over a limitation of an encoder-decoder model. An encoder-decider model encodes an input sequence to one fixed length vector from which the output is decoded at each time step. This issue may be seen as a problem when decoding long sequences because it may make it difficult for the neural network to cope with long sentences, such as those that are longer than the sentences in the training corpus. Applying an attention mechanism, an LLM 180 may predict the next word by searching for a set of positions in a source sentence where the most relevant information is concentrated. An LLM 180 may then predict the next word based on context vectors associated with these source positions and all the previously generated target words, such as textual data of a dictionary correlated to a prompt in a training data set. A “context vector,” as used herein, are fixed-length vector representations useful for document retrieval and word sense disambiguation.

With continued reference to FIG. 1, attention mechanism may include, without limitation, generalized attention self-attention, multi-head attention, additive attention, global attention, and the like. In generalized attention, when a sequence of words or an image is fed to an LLM 180, it may verify each element of the input sequence and compare it against the output sequence. Each iteration may involve the mechanism's encoder capturing the input sequence and comparing it with each element of the decoder's sequence. From the comparison scores, the mechanism may then select the words or parts of the image that it needs to pay attention to. In self-attention, an LLM 180 may pick up particular parts at different positions in the input sequence and over time compute an initial composition of the output sequence. In multi-head attention, an LLM 180 may include a transformer model of an attention mechanism. Attention mechanisms, as described above, may provide context for any position in the input sequence. For example, if the input data is a natural language sentence, the transformer does not have to process one word at a time. In multi-head attention, computations by an LLM 180 may be repeated over several iterations, each computation may form parallel layers known as attention heads. Each separate head may independently pass the input sequence and corresponding output sequence element through a separate head. A final attention score may be produced by combining attention scores at each head so that every nuance of the input sequence is taken into consideration. In additive attention (Bahdanau attention mechanism), an LLM 180 may make use of attention alignment scores based on a number of factors. Alignment scores may be calculated at different points in a neural network, and/or at different stages represented by discrete neural networks. Source or input sequence words are correlated with target or output sequence words but not to an exact degree. This correlation may take into account all hidden states and the final alignment score is the summation of the matrix of alignment scores. In global attention (Luong mechanism), in situations where neural machine translations are required, an LLM 180 may either attend to all source words or predict the target sentence, thereby attending to a smaller subset of words.

With continued reference to FIG. 1, multi-headed attention in encoder may apply a specific attention mechanism called self-attention. Self-attention allows models such as an LLM 180 or components thereof to associate each word in the input, to other words. As a non-limiting example, an LLM 180 may learn to associate the word “continuous”, with “insulation”. It's also possible that an LLM 180 learns that words structured in this pattern are typically a question and to respond appropriately. In some embodiments, to achieve self-attention, input may be fed into three distinct fully connected neural network layers to create query, key, and value vectors. A query vector may include an entity's learned representation for comparison to determine attention score. A key vector may include an entity's learned representation for determining the entity's relevance and attention weight. A value vector may include data used to generate output representations. Query, key, and value vectors may be fed through a linear layer; then, the query and key vectors may be multiplied using dot product matrix multiplication in order to produce a score matrix. The score matrix may determine the amount of focus for a word should be put on other words (thus, each word may be a score that corresponds to other words in the time-step). The values in score matrix may be scaled down. As a non-limiting example, score matrix may be divided by the square root of the dimension of the query and key vectors. In some embodiments, the softmax of the scaled scores in score matrix may be taken. The output of this softmax function may be called the attention weights. Attention weights may be multiplied by your value vector to obtain an output vector. The output vector may then be fed through a final linear layer.

With continued reference to FIG. 1, in order to use self-attention in a multi-headed attention computation, query, key, and value may be split into N vectors before applying self-attention. Each self-attention process may be called a “head.” Each head may produce an output vector and each output vector from each head may be concatenated into a single vector. This single vector may then be fed through the final linear layer discussed above. In theory, each head can learn something different from the input, therefore giving the encoder model more representation power.

With continued reference to FIG. 1, encoder of transformer may include a residual connection. Residual connection may include adding the output from multi-headed attention to the positional input embedding. In some embodiments, the output from residual connection may go through a layer normalization. In some embodiments, the normalized residual output may be projected through a pointwise feed-forward network for further processing. The pointwise feed-forward network may include a couple of linear layers with a ReLU activation in between. The output may then be added to the input of the pointwise feed-forward network and further normalized.

With continued reference to FIG. 1, transformer architecture may include a decoder. Decoder may a multi-headed attention layer, a pointwise feed-forward layer, one or more residual connections, and layer normalization (particularly after each sub-layer), as discussed in more detail above. In some embodiments, decoder may include two multi-headed attention layers. In some embodiments, decoder may be autoregressive. For the purposes of this disclosure, “autoregressive” means that the decoder takes in a list of previous outputs as inputs along with encoder outputs containing attention information from the input.

With continued reference to FIG. 1, in some embodiments, input to decoder may go through an embedding layer and positional encoding layer in order to obtain positional embeddings. Decoder may include a first multi-headed attention layer, wherein the first multi-headed attention layer may receive positional embeddings.

With continued reference to FIG. 1, first multi-headed attention layer may be configured to not condition to future tokens. As a non-limiting example, when computing attention scores on the word “am,” decoder should not have access to the word “fine” in “I am fine,” because that word is a future word that was generated after. The word “am” should only have access to itself and the words before it. In some embodiments, this may be accomplished by implementing a look-ahead mask. Look ahead mask is a matrix of the same dimensions as the scaled attention score matrix that is filled with “0s” and negative infinities. For example, the top right triangle portion of look-ahead mask may be filled with negative infinities. Look-ahead mask may be added to scaled attention score matrix to obtain a masked score matrix. Masked score matrix may include scaled attention scores in the lower-left triangle of the matrix and negative infinities in the upper-right triangle of the matrix. Then, when the softmax of this matrix is taken, the negative infinities will be zeroed out; this leaves zero attention scores for “future tokens.”

With continued reference to FIG. 1, second multi-headed attention layer may use encoder outputs as queries and keys and the outputs from the first multi-headed attention layer as values. This process matches the encoder's input to the decoder's input, allowing the decoder to decide which encoder input is relevant to put a focus on. The output from second multi-headed attention layer may be fed through a pointwise feedforward layer for further processing.

With continued reference to FIG. 1, the output of the pointwise feedforward layer may be fed through a final linear layer. This final linear layer may act as a classifier. This classifier may be as big as the number of classes that you have. For example, if you have 10,000 classes for 10,000 words, the output of that classifier will be of size 10,000. The output of this classifier may be fed into a softmax layer which may serve to produce probability scores between zero and one. The index may be taken of the highest probability score in order to determine a predicted word.

With continued reference to FIG. 1, decoder may take this output and add it to the decoder inputs. Decoder may continue decoding until a token is predicted. Decoder may stop decoding once it predicts an end token.

With continued reference to FIG. 1, in some embodiment, decoder may be stacked N layers high, with each layer taking in inputs from the encoder and layers before it. Stacking layers may allow an LLM 180 to learn to extract and focus on different combinations of attention from its attention heads.

With continued reference to FIG. 1, an LLM 180 may receive an input (e.g., user query 182). Input may include a string of one or more characters. Inputs may additionally include unstructured data. For example, input may include one or more words, a sentence, a paragraph, a thought, a query, and the like. A “query” for the purposes of the disclosure is a string of characters that poses a question. In some embodiments, input may be received from a remote device 124. Remote device 124 may be any computing device that is used by a user 128. As non-limiting examples, remote device 124 may include desktops, laptops, smartphones, tablets, and the like. In some embodiments, input (e.g., user query 182) may include any set of data associated with representative part model 120.

With continued reference to FIG. 1, an LLM 180 may generate at least one annotation as an output. At least one annotation may be any annotation as described herein. In some embodiments, an LLM 180 may include multiple sets of transformer architecture as described above. Output may include a textual output. A “textual output,” for the purposes of this disclosure is an output comprising a string of one or more characters. Textual output may include, for example, a plurality of annotations for unstructured data. In some embodiments, textual output may include a phrase or sentence identifying the status of a user query 182. In some embodiments, textual output may include a sentence or plurality of sentences describing a response to a user query 182. As a non-limiting example, this may include restrictions, timing, advice, design problem 146, benefits, design solution 148, part feature 136, design reference 140, part progress class label 144, and the like.

With continued reference to FIG. 1, processor 104 may be configured to create a user interface data structure 186. As used in this disclosure, “user interface data structure” is a data structure representing a specialized formatting of data on a computer configured such that the information can be effectively presented for a user interface. User interface data structure 186 may include the plurality of components 116. In some cases, user interface data structure 186 may further include the design solution 148, design problem 146, representative part model 120, part feature 136, building part 160, part progress class label 144, user prompt 152, and the like. In some cases, user interface data structure 186 further includes any data as described in this disclosure. Processor 104 may be configured to generate user interface data structure 186 using any combination of data as described in this disclosure.

With continued reference to FIG. 1, processor 104 may further be configured to transmit user interface data structure 186 to remote device 124. Transmitting may include, and without limitation, transmitting using a wired or wireless connection, direct, or indirect, and between two or more components, circuits, devices, systems, and the like, which allows for reception and/or transmittance of data and/or signal(s) therebetween. Data and/or signals therebetween may include, without limitation, electrical, electromagnetic, magnetic, video, audio, radio, and microwave data and/or signals, combinations thereof, and the like, among others. Processor 104 may transmit the data described above to a database wherein the data may be accessed from a database, processor 104 may further transmit the data above to a device display or another computing device.

With continued reference to FIG. 1, memory 108 contains instructions configuring processor 104 to generate user interface 156 displaying representative part model 120 with part progress class label 144, design problem 146, and design solution 148 on a remote device 124. Additionally or alternatively, processor 104 may be configured to transmit user interface data structure 186 to a graphical user interface (GUI) of user interface 156. For the purposes of this disclosure, a “user interface” is a means by which a user and a computer system interact; for example, through the use of input devices and software. A user interface may include graphical user interface, command line interface (CLI), menu-driven user interface, touch user interface, voice user interface (VUI), form-based user interface, any combination thereof and the like. In some embodiments, a user may interact with the user interface using a computing device and/or a processor distinct from and communicatively connected to processor. For example, a smart phone, smart, tablet, or laptop operated by the user. A user interface may include one or more graphical locator and/or cursor facilities allowing a user to interact with graphical models and/or combinations thereof, for instance using a touchscreen, touchpad, mouse, keyboard, and/or other manual data entry devices. A “graphical user interface,” as used herein, is a user interface that allows users to interact with electronic devices through visual representations on the devices. In some cases, GUI may be communicatively connected to processor 104 and configured to receive user interface data structure 186. Additionally or alternatively, GUI may be configured to display the plurality of components as a function of the user interface data structure 186. In some embodiments, GUI may include icons, menus, other visual indicators, or representations (graphics), audio indicators such as primary notation, and display information and related user controls. A menu may contain a list of choices and may allow users to select one from them. A menu bar may be displayed horizontally across the screen such as pull-down menu. When any option is clicked in this menu, then the pull-down menu may appear. A menu may include a context menu that appears only when the user performs a specific action. An example of this is pressing the right mouse button. When this is done, a menu may appear under the cursor. Files, programs, web pages and the like may be represented using a small picture in a graphical user interface. Persons skilled in the art, upon reviewing the entirety of this disclosure, will be aware of various ways in which a graphical user interface and/or elements thereof may be implemented and/or used as described in this disclosure.

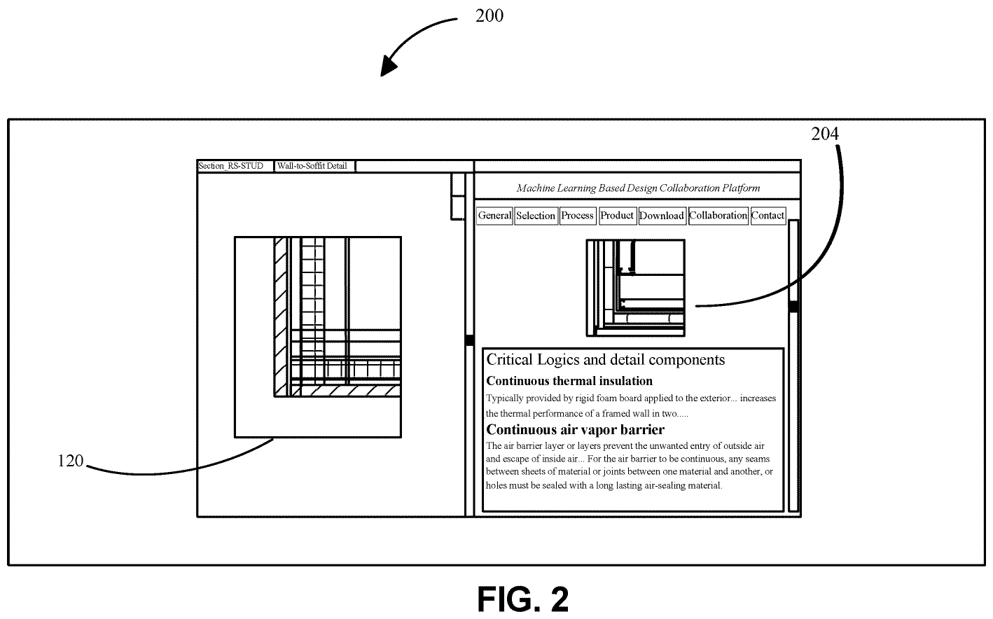

With continued reference to FIG. 1, GUI may display data to user 128 such that user 128 may view the data generated and interact with the data. User 128 may view the design solution 148 in a visual format such as a visual drawing wherein a user 128 may view the visual drawing and make any corresponding changes. In some cases, design solution 148 may contain more than one design solution 148 wherein each design solution 148 may contain its own individual visual drawing. User 128 may interact with GUI to scroll through the given design solutions 148 and select the one that may be most appropriate. Similarly, a user may interact with GUI and select one or more components from the plurality of components. In some cases, more than one components 116 may be associated with a particular model wherein a user may select the appropriate components from a list. GUI may be consistent with the user interfaces depicted within FIGS. 2-4 below.

With continued reference to FIG. 1, in some embodiments, generating user interface 156 may include generating a user input field 188, wherein a user 128 queries representative part model 120 from part database 132 using a keyword related to part progress class label 144. As a non-limiting example, keyword related to part progress class label 144 may include any portion of part progress class label 144 thereof. For example, and without limitation, keyword related to part progress class label 144 may include ‘in progress’ if a user 128 wants to retrieve representative part model 120 that has design progress state 164 as ‘In Progress.’ For example, and without limitation, keyword related to part progress class label 144 may include ‘roof’ if a user 128 wants to retrieve representative part model 120 that has region class 162 as ‘roof.’ In some embodiments, user interface 156 may include a user input field 188. As used in this disclosure, a “user input field” is a graphical or interactive element in GUI that allows a user to input or enter data. In some cases, user input field may be configured to receive user query 182 related to representative part model 120. In a non-limiting example, user input field 188 may include a text box, dropdown menu, checkbox, radio button, and/or any other interactive components. In some cases, user input field may include an event handler that respond to user interactions, wherein the “event handler,” for the purpose of this disclosure, is a piece of computer program or software function that is associated with a specific event, such as user 128 inputting user query 182 interacting with corresponding user input field.

With continued reference to FIG. 1, processor 104 may be configured to generate a modified part model as a function of determining the plurality of components 116. Processor 104 may generate a modified part model having at least one component of the plurality of components 116. For example, processor 104 may add a single clip to representative part model 120 wherein the clip is a component within the plurality of components 116. In some cases, processor 104 may complete representative part model 120 by using BIM integrated objects that represent key points that may need to be added to the model. In some cases, user 128 may interact with GUI and drag and drop BIM integrated objects onto representative part model 120 to create modified part model. BIM integrated objects may be presented as a list to user 128, wherein a user 128 may interact with GUI and click and drop selected objects directly onto representative part model 120. GUI may be configured to display multiple BIM integrated objects wherein a user 128 may, for example, select to add an air vapor barrier because of the design guidance 150 and/or design solution 148 provided by the machine-learning modules discussed above. This click and drop feature may save time and labor during the design development and construction documentation phases of the design process. In some cases, generating modified part model includes generating modified part model as a function of user input. User input may include any interaction between user 128 and GUI and/or processor. For example, the click and drop of an integrated object may constitute a user input. In some cases, GUI may display a plurality of components for a user to select from wherein selection of the plurality of components.

With continued reference to FIG. 1, apparatus 100 and/or GUI may provide a user with information regarding each design solution. For example, a particular design solution may contain corresponding definitions, examples, and reading material in order to educate a user on the particular design solution and how it may be necessary. In some cases, a user may ‘hover’ over each design solution 148 wherein processor 104 may display the corresponding information associated with each design solution 148. In some cases, GUI may display plurality of components 116 wherein a user may view each component 116 and view the corresponding information associated with the component such as material, educational information describing the component and its use, and the like. In some cases, a user may ‘hover’ over a particular component 116 displayed in order to view the corresponding information associated with component 116. In some cases, a user may ‘select’ or view each component 116 in order to determine if the component was properly selected by processor 104 and/or if the component 116 properly relates to the representative part model. In some cases, information associated with component 116 may include information such as the particular design solution 148 associated with component 116. For example, processor 104 may display information to user 128 on why a particular component was selected such as what design problem was addressed and what design solution was addressed as well. In some cases a user may select, through the GUI, a particular component 116 selection of the component may allow a user to view various details associated the component such as the manufacturer involved, its ease of use, its case of installation, its sustainability, and any other relevant information that may be necessary for selection of a component.

With continued reference to FIG. 1, plurality of components 116 may be determined as a function of user input. “User input” for the purposes of this disclosure is any interaction between a user and a computing device wherein the interaction conveys information to the computing device. For example, selecting a checkbox based on user input may signify to processor 104 that a box was checked wherein processor 104 may execute a function associated with the checkbox. In some cases, processor 104 may provide a user 128 with a plurality of components 116 to choose from. User 128 may input parameters in order to narrow down the components 116 to components that may be specific to the user's 132 needs. For example, user 128 may interact with GUI wherein user 128 may filter through the determined components by signifying to computing device that only particular components should be showed, such as for example, components that focus on sustainability or affordability. In some cases, user 128 may narrow down results by inputting constraints such as, but not limited to, constraints with respect to sustainability, affordability, availability of the component, case of maintenance, user ratings, case of installation and the like. In some cases, components 116 may be rated wherein a user 128 may interact with GUI in order to prioritize various components 116 over others. For example, a user 128 may input a command into computing device to signify that components 116 that are the most affordable should be prioritized. In some cases, each constraint described above may contain preference weights wherein each constraint may contain a weight that signifies to computing device to sort components 116 based on a particular weight of each component 116. In some cases, apparatus 100 may utilize a multi-objective optimization wherein a user may select multiple objectives and/or constraints that may output a corresponding component most closely associated with the constraints. For example, a user may desire to search for a component that maxims affordability, and sustainability while ignoring case of installation. In another nonlimiting example, a user may select one or more constraints to be maximized while minimizing one or more other constraints. GUI may display the components in a descending order wherein the first component may have the highest degree of match with respect to the selected constraints. In some cases components may be displayed in a list, wherein user 128 may scroll, using a computing device and/or a remote device, through the list in order to view components. In some cases, the order of the list may be determined based on user input wherein a user may input a particular priority of components being displayed. In some cases, design solution 148 may be displayed in visual format on representative part model, wherein a user may interact with a computing device and select each design solution 148 on representative part model 120 in order to view the information corresponding to the design solution 148 and the corresponding components 116 that would aid in the design solution. In some cases, a user may compare GUI to display several components to a user, wherein user 128 may select the component that may be most applicable. Each component 116 may include data relating to the constraints that the user has entered as described above. In some cases, components 116 may contain data indicating the degree of match to a particular constraint. For example, a component that is highly affordable may contain a higher degree of match with respect to an ‘affordability’ constraint whereas a product that is not so affordable may contain a lower degree of match with respect to an affordability constraint. In some cases, GUI may display components 116 based on a degree of match and provide them in descending order wherein a first component may contain a higher degree of match than a second component. In some cases, GUI may display the degrees of match to a user, wherein a user may visualize the degrees of match associated with each constraint. For example, a component may contain a higher degree of match with respect to affordability but a lower degree of match with respect to ‘sustainability’. User 128 may view the degrees of match to select the component that best satisfies the user's need.

With continued reference to FIG. 1, apparatus and/or GUI may include a collaboration feature. A “collaboration feature” for the purposes of this disclosure is device and/or a computer program capable of allowing multiple users to view similar information and any corresponding changes made to the information without the having to share the information through another program such as an email service. Collaboration feature may allow for multiple users to view a similar part wherein each user may view the design problems 146 and design solutions associated with the part. In some cases, a user may seek to share part with a manufacturer wherein user and the manufacturer may view the same part in real time and make any corresponding changes. In some cases, multiple users may view a single part wherein each user may make changes to the part. In some cases, collaboration feature may include comment boxes wherein users may post comments associated with representative part model 120 and/or any other data displayed wherein other users may view the comments and make any corresponding actions. In some cases, apparatus may provide a weblink for user 128 to use in order to view a particular representative part model as a part of collaboration feature. In some cases, the weblink may direct a user to a database wherein users may view representative part model through remote device connected to database. In some cases collaboration feature may allow users to share various parts with manufacturers and/or consultants in order to receive feedback on the part that is sought to be created.

With continued reference to FIG. 1, processor 104 may further be configured to generate a product information sheet as a function of representative part model 120, design problem 146, design solution 148, components 116 and any other data described within this disclosure. A “product information sheet” as disclosed herein is data describing representative part model and any additional parts that may have been added or altered as a result of the computing. Product information sheet may contain information such as materials used, dimensions, manufacturing time, owner of the part, entity associated with the owner of the part, manufacturers involved, and any other relevant information.

Now referencing FIG. 2, a screenshot 200 of an exemplary embodiment of a generated solution as a function of a design problem as described in this disclosure is shown. Representative part model 120 is shown on the left as a section of a print. Representative part model 120 may be converted into a GAN-generated drawing 204 (e.g., design solution 148), shown on the right, to provide better visualization of a geometric configuration of the design area. GAN-generated drawing may be used by processor 104 to categorize representative part model 120 to design problems. Representative part model 120 may be categorized into a design problem 146 and design solutions 148 that are generated as a result. Processor 104 may suggest possible design solutions to complete building design.

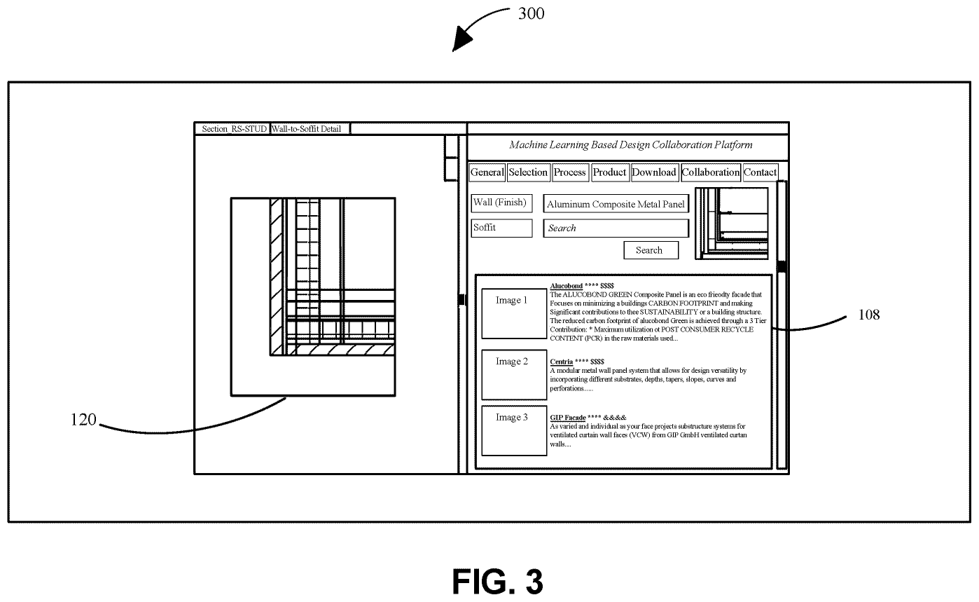

Now referring to FIG. 3, a screenshot 300 of an exemplary embodiment of a database of components 116 used to select components for representative part model 120 is illustrated. In an embodiment, a user may be displayed a list of recommended components from various manufacturers that may be stored in component database 112. User may be able to browse all components in component database 112. Alternatively or additionally, a user may be shown components of component database 112 that pertains to materials needed for representative part model 120 or materials needed for a design solution or components based on categorized representative part model 120 to design problems.

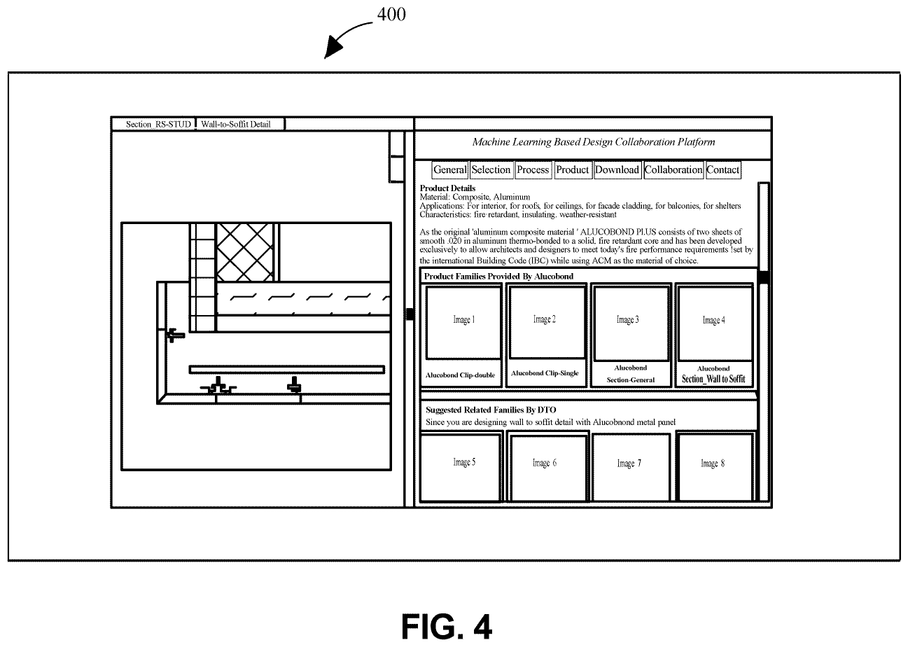

Now referring to FIG. 4, a screenshot 400 of an exemplary embodiment of a click and drop feature of apparatus 100. Click and drag feature may be used to add BIM integrated objects onto representative part model 120. Processor 104 may suggest BIM integrated objects to be added as a function of the design solution and components selected out of component database 112. A user may click and drop a BIM component into any desired spot on representative part model 120. BIM integrated objects may be used to designate build features such as air vapor barriers, rigid insulation, studs, or the like. Adding the BIM integrated objects into representative part model 120 may be a finishing step to making a complete construction drawing.

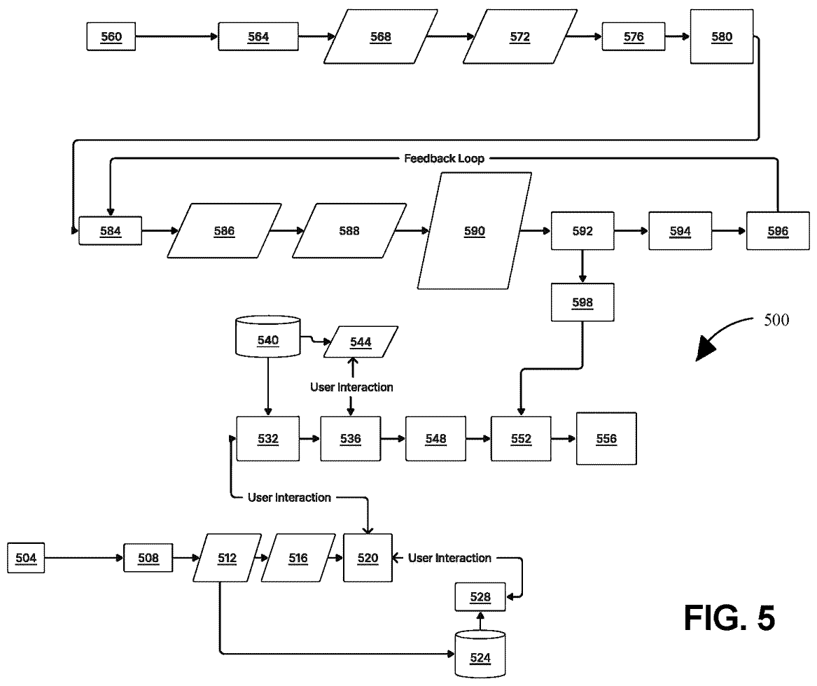

Referring now to FIG. 5, a flow diagram of an exemplary embodiment of an apparatus 500 for determining and solving design problems using machine-learning is described. At step 504, user may input a BIM model and/or project into apparatus 500. Inputting may include inputting by selecting an add-on of an existing design software, uploading a BIM model to a standalone software, and/or a computing device recognizing a BIM model/project within a design software and receiving the BIM model. At step 508, apparatus 500 may receive data from the user's BIM model and/or project. Apparatus may receive data in any way described within this disclosure. At step 512, apparatus 500 may predict and/or classify a user's design problems using a first machine-learning model (e.g., problem machine-learning model 172) as described above. At step 516 apparatus may generate design solutions using a second machine-learning module. In some cases, apparatus may populate an interactive diagram based on the design problems. At step 520, Apparatus 500 may generate and/or display an interactive diagram in which a user may interact with the classified objects. In some cases, the diagram may serve as a communication channel between apparatus and a user. In some cases, apparatus 500 may generate a vector-based interactive design diagram in real time based on the classified design problem. In some cases, at step 524, apparatus 500 apparatus may receive design guidance from a database and at step 528, apparatus 500 may display design guidance. For example, a user may select a portion of a displayed element wherein apparatus 500 may display related design guidance similar to the selected portion. Design guidance may be a text description and/or combinations of images, diagrams, and text.

With continued reference to FIG. 5, a user may interact with the interactive display displayed at step 520. At step 532, a user may explore products on apparatus 500. Apparatus 500 may display products only relevant based on user interaction and/or selection. For example, when a user clicks a portion of a displayed element, apparatus 500 may only display components and/or products similar to the selected portion. A user may navigate through a variety of options as described in FIGS. 1-4, wherein a user may select similar components and/or products based on the selected portion. In some cases, a user may navigate components based on predefined parameters. At step 536, a user may employ a ‘smart product search’ wherein a user may navigate through displayed components and/or products by sorting the components and/or products to meet the user's requirements and/or preferences. A user may set parameters with various weights wherein a computing device communicatively connected to apparatus 500 may sort components based on the preferences and their corresponding weights. For example, a user may set a preference of ‘affordability’ with a weight of 3, a preference of ‘availability’ with a weight of 3, and a preference of price with a weight of 2. Apparatus 500 may sort a list of components to conform to the user's preferences and/or requirements using a multi-objective optimization model. In some cases, a building product database may provide the components to a user. At step 540, apparatus 500 may receive components and/or products from a building product database. In some cases, apparatus 500 may receive products from a building product database, wherein the products may be sorted, at step 544 using a multi-objective optimization model to sort the products based on a user's requirements. In some cases, user may interact with the multi objective optimization model such as, for example, by interacting with a user interface to input and/or select requirements, setting a weight of a particular requirement using a sliding bar configured to weight and the like. In some cases, at step 548, apparatus 500 may employ a ‘smart product comparison’ wherein products are shown as a function of the requirements in step 536. In some cases, a user may view the components and/or products visually such as in a visual format. In some cases, a product may be shown along with its corresponding weights. In some cases, each product may be viewed side by side with another product. In some cases, a list of products may be displayed wherein a first product having a higher degree of match with a user's preference may be shown first. In some cases, at step 552, apparatus may display product specifications that are associated with a particular product. Apparatus 500 may enable a fully integrated specification feature, wherein a user may view the specification of a particular product without having to use a 3rd party software to lookup details about a particular component. In some cases, at step 556, a user may select a particular product wherein apparatus 500 may integrate the particular product into the BIM model that had been inputted by a user in step 504. Users may click and place a component into their BIM model. These BIM integrated objects may be provided by manufacturers. In some cases, users may be able to specify products as a basis of design and use their BIM component directly from apparatus 500. In some cases, this may eliminate any cumbersome process of finding a particular and/or correct BIM component using an online search.

With continued reference to FIG. 5, at step 560, a user may instead input a design image, rather than a BIM model as specified in step 504. The design image can be a rendered image of a project or any reference image that the user has. At step 562, apparatus 500 may receive the design image. The design image may be received via an add-on as described in this disclosure wherein apparatus 500 may be used in conjunction with a 3rd party design software and receive design image form the 3rd party software. At step 568, apparatus 500 may predict physical and optical parameters (POP) of design image wherein the physical and optical parameters may include camera parameters of each pixel, 3d depth of each pixel, light condition of each pixel and the like. At step 572, apparatus may segment the design image onto more than one building part, wherein each building part may represent a separate component of an overall model within design image. For example, apparatus 500 may segment the design image into multiple building parts such as a black matter exterior wall panel, a gray glossy interior painted wall, a window, a door, and the like. At step 576, a user may select one segment of the design image representing a building part wherein a user may view products similar to the selected part. For example, a user may select an exterior wall, wherein a user may view similar building parts corresponding to an exterior wall. At step 580, apparatus may use classification of the selected region to provide products for a user to explore similar to steps 532, 536, 548, 552 and/or 556 as described above. a user, may select parameters of a particular product using a ‘smart product search’ wherein a user may view products similar to the selected product. At step 584, a user may select a particular product to explore further. At step 586, apparatus 500 may further determine physical and optical parameters of the selected image. Apparatus 500 may determine physical and optical parameters using a machine-learning model such as a machine-learning model as described in this disclosure. At step 588, apparatus 500 may use a fourth machine-learning model to segment the selected product and acquire only a relevant region as a style reference. At step 590, apparatus may use a fifth machine-learning model in order to transfer the style of the selected region of the design image on the acquired product style reference. Using the physical and optical parameters of both the design image and the selected product image, apparatus 500 may match the style reference's physical and optical parameters to the design image. At step 592, apparatus 500 may display an updated image that near-perfectly mapped product texture with correct scale, light and perspective. At step 594, apparatus may display similar or relevant products based on the selected product. Similar products may be based on aesthetic similarity, visual similarity, performance similarity and the like. At step 596, a user may select another product to explore wherein apparatus may receive the selected product similar to step 584 and perform determinations based on the selected product. In some cases, following step 592, at step 598 a user may specify the chosen product from step 584 as the basis for their design. As a result apparatus may receive product specification as indicated in step 552 and allow a user to drack and drop the product as indicated in step 556.

Referring now to FIG. 6, an exemplary embodiment of a machine-learning module 600 that may perform one or more machine-learning processes as described in this disclosure is illustrated. Machine-learning module may perform determinations, classification, and/or analysis steps, methods, processes, or the like as described in this disclosure using machine-learning processes. A “machine-learning process,” as used in this disclosure, is a process that automatedly uses training data 604 to generate an algorithm instantiated in hardware or software logic, data structures, and/or functions that will be performed by a computing device/module to produce outputs 608 given data provided as inputs 612; this is in contrast to a non-machine-learning software program where the commands to be executed are determined in advance by a user and written in a programming language.

With continued reference to FIG. 6, “training data,” as used herein, is data containing correlations that a machine-learning process may use to model relationships between two or more categories of data elements. For instance, and without limitation, training data 604 may include a plurality of data entries, also known as “training examples,” each entry representing a set of data elements that were recorded, received, and/or generated together; data elements may be correlated by shared existence in a given data entry, by proximity in a given data entry, or the like. Multiple data entries in training data 604 may evince one or more trends in correlations between categories of data elements; for instance, and without limitation, a higher value of a first data element belonging to a first category of data element may tend to correlate to a higher value of a second data element belonging to a second category of data element, indicating a possible proportional or other mathematical relationship linking values belonging to the two categories. Multiple categories of data elements may be related in training data 604 according to various correlations; correlations may indicate causative and/or predictive links between categories of data elements, which may be modeled as relationships such as mathematical relationships by machine-learning processes as described in further detail below. Training data 604 may be formatted and/or organized by categories of data elements, for instance by associating data elements with one or more descriptors corresponding to categories of data elements. As a non-limiting example, training data 604 may include data entered in standardized forms by persons or processes, such that entry of a given data element in a given field in a form may be mapped to one or more descriptors of categories. Elements in training data 604 may be linked to descriptors of categories by tags, tokens, or other data elements; for instance, and without limitation, training data 604 may be provided in fixed-length formats, formats linking positions of data to categories such as comma-separated value (CSV) formats and/or self-describing formats such as extensible markup language (XML), JavaScript Object Notation (JSON), or the like, enabling processes or devices to detect categories of data.

Alternatively or additionally, and with continued reference to FIG. 6, training data 604 may include one or more elements that are not categorized; that is, training data 604 may not be formatted or contain descriptors for some elements of data. Machine-learning algorithms and/or other processes may sort training data 604 according to one or more categorizations using, for instance, natural language processing algorithms, tokenization, detection of correlated values in raw data and the like; categories may be generated using correlation and/or other processing algorithms. As a non-limiting example, in a corpus of text, phrases making up a number “n” of compound words, such as nouns modified by other nouns, may be identified according to a statistically significant prevalence of n-grams containing such words in a particular order; such an n-gram may be categorized as an element of language such as a “word” to be tracked similarly to single words, generating a new category as a result of statistical analysis. Similarly, in a data entry including some textual data, a person's name may be identified by reference to a list, dictionary, or other compendium of terms, permitting ad-hoc categorization by machine-learning algorithms, and/or automated association of data in the data entry with descriptors or into a given format. The ability to categorize data entries automatedly may enable the same training data 604 to be made applicable for two or more distinct machine-learning algorithms as described in further detail below. Training data 604 used by machine-learning module 600 may correlate any input data as described in this disclosure to any output data as described in this disclosure. As a non-limiting illustrative example, input data may include representative part model 120, part feature 136, building part 160, part progress class label 144, region class 162, design progress state 164, design reference 140, design problem 146, user query 182, and the like. As a non-limiting illustrative example, output data may include part feature 136, building part 160, part progress class label 144, region class 162, design progress state 164, design reference 140, design problem 146, design solution 148, user prompt 152, component 116, and the like.

Further referring to FIG. 6, training data may be filtered, sorted, and/or selected using one or more supervised and/or unsupervised machine-learning processes and/or models as described in further detail below; such models may include without limitation a training data classifier 616. Training data classifier 616 may include a “classifier,” which as used in this disclosure is a machine-learning model as defined below, such as a data structure representing and/or using a mathematical model, neural net, or program generated by a machine-learning algorithm known as a “classification algorithm,” as described in further detail below, that sorts inputs into categories or bins of data, outputting the categories or bins of data and/or labels associated therewith. A classifier may be configured to output at least a datum that labels or otherwise identifies a set of data that are clustered together, found to be close under a distance metric as described below, or the like. A distance metric may include any norm, such as, without limitation, a Pythagorean norm. Machine-learning module 600 may generate a classifier using a classification algorithm, defined as a processes whereby a computing device and/or any module and/or component operating thereon derives a classifier from training data 604. Classification may be performed using, without limitation, linear classifiers such as without limitation logistic regression and/or naive Bayes classifiers, nearest neighbor classifiers such as k-nearest neighbors classifiers, support vector machines, least squares support vector machines, fisher's linear discriminant, quadratic classifiers, decision trees, boosted trees, random forest classifiers, learning vector quantization, and/or neural network-based classifiers. As a non-limiting example, training data classifier 616 may classify elements of training data to user cohort or part cohort. As a non-limiting example, user cohort may include a cohort related to a user, such as gender, age, occupation, and the like. As a non-limiting example, user cohort may include a cohort related to a representative part model, such as design class; construction types, climate zones, use and occupancy types, and the like.

With continued reference to FIG. 6, computing device may be configured to generate a classifier using a Naïve Bayes classification algorithm. Naïve Bayes classification algorithm generates classifiers by assigning class labels to problem instances, represented as vectors of element values. Class labels are drawn from a finite set. Naïve Bayes classification algorithm may include generating a family of algorithms that assume that the value of a particular element is independent of the value of any other element, given a class variable. Naïve Bayes classification algorithm may be based on Bayes Theorem expressed as P(A/B)=P(B/A) P(A)÷P(B), where P(A/B) is the probability of hypothesis A given data B also known as posterior probability; P(B/A) is the probability of data B given that the hypothesis A was true; P(A) is the probability of hypothesis A being true regardless of data also known as prior probability of A; and P(B) is the probability of the data regardless of the hypothesis. A naïve Bayes algorithm may be generated by first transforming training data into a frequency table. Computing device may then calculate a likelihood table by calculating probabilities of different data entries and classification labels. Computing device may utilize a naïve Bayes equation to calculate a posterior probability for each class. A class containing the highest posterior probability is the outcome of prediction. Naïve Bayes classification algorithm may include a gaussian model that follows a normal distribution. Naïve Bayes classification algorithm may include a multinomial model that is used for discrete counts. Naïve Bayes classification algorithm may include a Bernoulli model that may be utilized when vectors are binary.

With continued reference to FIG. 6, Computing device may be configured to generate a classifier using a K-nearest neighbors (KNN) algorithm. A “K-nearest neighbors algorithm” as used in this disclosure, includes a classification method that utilizes feature similarity to analyze how closely out-of-sample-features resemble training data to classify input data to one or more clusters and/or categories of features as represented in training data; this may be performed by representing both training data and input data in vector forms, and using one or more measures of vector similarity to identify classifications within training data, and to determine a classification of input data. K-nearest neighbors algorithm may include specifying a K-value, or a number directing the classifier to select the k most similar entries training data to a given sample, determining the most common classifier of the entries in the database, and classifying the known sample; this may be performed recursively and/or iteratively to generate a classifier that may be used to classify input data as further samples. For instance, an initial set of samples may be performed to cover an initial heuristic and/or “first guess” at an output and/or relationship, which may be seeded, without limitation, using expert input received according to any process as described herein. As a non-limiting example, an initial heuristic may include a ranking of associations between inputs and elements of training data. Heuristic may include selecting some number of highest-ranking associations and/or training data elements.

With continued reference to FIG. 6, generating k-nearest neighbors algorithm may generate a first vector output containing a data entry cluster, generating a second vector output containing an input data, and calculate the distance between the first vector output and the second vector output using any suitable norm such as cosine similarity, Euclidean distance measurement, or the like. Each vector output may be represented, without limitation, as an n-tuple of values, where n is at least two values. Each value of n-tuple of values may represent a measurement or other quantitative value associated with a given category of data, or attribute, examples of which are provided in further detail below; a vector may be represented, without limitation, in n-dimensional space using an axis per category of value represented in n-tuple of values, such that a vector has a geometric direction characterizing the relative quantities of attributes in the n-tuple as compared to each other. Two vectors may be considered equivalent where their directions, and/or the relative quantities of values within each vector as compared to each other, are the same; thus, as a non-limiting example, a vector represented as [5, 10, 15] may be treated as equivalent, for purposes of this disclosure, as a vector represented as [1, 2, 3]. Vectors may be more similar where their directions are more similar, and more different where their directions are more divergent; however, vector similarity may alternatively or additionally be determined using averages of similarities between like attributes, or any other measure of similarity suitable for any n-tuple of values, or aggregation of numerical similarity measures for the purposes of loss functions as described in further detail below. Any vectors as described herein may be scaled, such that each vector represents each attribute along an equivalent scale of values. Each vector may be “normalized,” or divided by a “length” attribute, such as a length attribute l as derived using a Pythagorean norm: l=\sqrt{Σᵢ₌₀ⁿaᵢ²}, where aᵢ is attribute number i of the vector. Scaling and/or normalization may function to make vector comparison independent of absolute quantities of attributes, while preserving any dependency on similarity of attributes; this may, for instance, be advantageous where cases represented in training data are represented by different quantities of samples, which may result in proportionally equivalent vectors with divergent values.

With further reference to FIG. 6, training examples for use as training data may be selected from a population of potential examples according to cohorts relevant to an analytical problem to be solved, a classification task, or the like. Alternatively or additionally, training data may be selected to span a set of likely circumstances or inputs for a machine-learning model and/or process to encounter when deployed. For instance, and without limitation, for each category of input data to a machine-learning process or model that may exist in a range of values in a population of phenomena such as images, user data, process data, physical data, or the like, a computing device, processor, and/or machine-learning model may select training examples representing each possible value on such a range and/or a representative sample of values on such a range. Selection of a representative sample may include selection of training examples in proportions matching a statistically determined and/or predicted distribution of such values according to relative frequency, such that, for instance, values encountered more frequently in a population of data so analyzed are represented by more training examples than values that are encountered less frequently. Alternatively or additionally, a set of training examples may be compared to a collection of representative values in a database and/or presented to a user, so that a process can detect, automatically or via user input, one or more values that are not included in the set of training examples. Computing device, processor, and/or module may automatically generate a missing training example; this may be done by receiving and/or retrieving a missing input and/or output value and correlating the missing input and/or output value with a corresponding output and/or input value collocated in a data record with the retrieved value, provided by a user and/or other device, or the like.

With continued reference to FIG. 6, computer, processor, and/or module may be configured to preprocess training data. “Preprocessing” training data, as used in this disclosure, is transforming training data from raw form to a format that can be used for training a machine-learning model. Preprocessing may include sanitizing, feature selection, feature scaling, data augmentation and the like.

With continued reference to FIG. 6, computer, processor, and/or module may be configured to sanitize training data. “Sanitizing” training data, as used in this disclosure, is a process whereby training examples are removed that interfere with convergence of a machine-learning model and/or process to a useful result. For instance, and without limitation, a training example may include an input and/or output value that is an outlier from typically encountered values, such that a machine-learning algorithm using the training example will be adapted to an unlikely amount as an input and/or output; a value that is more than a threshold number of standard deviations away from an average, mean, or expected value, for instance, may be eliminated. Alternatively or additionally, one or more training examples may be identified as having poor quality data, where “poor quality” is defined as having a signal to noise ratio below a threshold value. Sanitizing may include steps such as removing duplicative or otherwise redundant data, interpolating missing data, correcting data errors, standardizing data, identifying outliers, and the like. In a nonlimiting example, sanitization may include utilizing algorithms for identifying duplicate entries or spell-check algorithms.

As a non-limiting example, and with further reference to FIG. 6, images used to train an image classifier or other machine-learning model and/or process that takes images as inputs or generates images as outputs may be rejected if image quality is below a threshold value. For instance, and without limitation, computing device, processor, and/or module may perform blur detection, and eliminate one or more Blur detection may be performed, as a non-limiting example, by taking Fourier transform, or an approximation such as a Fast Fourier Transform (FFT) of the image and analyzing a distribution of low and high frequencies in the resulting frequency-domain depiction of the image; numbers of high-frequency values below a threshold level may indicate blurriness. As a further non-limiting example, detection of blurriness may be performed by convolving an image, a channel of an image, or the like with a Laplacian kernel; this may generate a numerical score reflecting a number of rapid changes in intensity shown in the image, such that a high score indicates clarity and a low score indicates blurriness. Blurriness detection may be performed using a gradient-based operator, which measures operators based on the gradient or first derivative of an image, based on the hypothesis that rapid changes indicate sharp edges in the image, and thus are indicative of a lower degree of blurriness. Blur detection may be performed using Wavelet-based operator, which takes advantage of the capability of coefficients of the discrete wavelet transform to describe the frequency and spatial content of images. Blur detection may be performed using statistics-based operators take advantage of several image statistics as texture descriptors in order to compute a focus level. Blur detection may be performed by using discrete cosine transform (DCT) coefficients in order to compute a focus level of an image from its frequency content.

With continued reference to FIG. 6, computing device, processor, and/or module may be configured to precondition one or more training examples. For instance, and without limitation, where a machine-learning model and/or process has one or more inputs and/or outputs requiring, transmitting, or receiving a certain number of bits, samples, or other units of data, one or more training examples' elements to be used as or compared to inputs and/or outputs may be modified to have such a number of units of data. For instance, a computing device, processor, and/or module may convert a smaller number of units, such as in a low pixel count image, into a desired number of units, for instance by upsampling and interpolating. As a non-limiting example, a low pixel count image may have 100 pixels, however a desired number of pixels may be 128. Processor may interpolate the low pixel count image to convert the 100 pixels into 128 pixels. It should also be noted that one of ordinary skill in the art, upon reading this disclosure, would know the various methods to interpolate a smaller number of data units such as samples, pixels, bits, or the like to a desired number of such units. In some instances, a set of interpolation rules may be trained by sets of highly detailed inputs and/or outputs and corresponding inputs and/or outputs downsampled to smaller numbers of units, and a neural network or other machine-learning model that is trained to predict interpolated pixel values using the training data. As a non-limiting example, a sample input and/or output, such as a sample picture, with sample-expanded data units (e.g., pixels added between the original pixels) may be input to a neural network or machine-learning model and output a pseudo replica sample-picture with dummy values assigned to pixels between the original pixels based on a set of interpolation rules. As a non-limiting example, in the context of an image classifier, a machine-learning model may have a set of interpolation rules trained by sets of highly detailed images and images that have been downsampled to smaller numbers of pixels, and a neural network or other machine-learning model that is trained using those examples to predict interpolated pixel values in a facial picture context. As a result, an input with sample-expanded data units (the ones added between the original data units, with dummy values) may be run through a trained neural network and/or model, which may fill in values to replace the dummy values. Alternatively or additionally, processor, computing device, and/or module may utilize sample expander methods, a low-pass filter, or both. As used in this disclosure, a “low-pass filter” is a filter that passes signals with a frequency lower than a selected cutoff frequency and attenuates signals with frequencies higher than the cutoff frequency. The exact frequency response of the filter depends on the filter design. Computing device, processor, and/or module may use averaging, such as luma or chroma averaging in images, to fill in data units in between original data units.

In some embodiments, and with continued reference to FIG. 6, computing device, processor, and/or module may down-sample elements of a training example to a desired lower number of data elements. As a non-limiting example, a high pixel count image may have 256 pixels, however a desired number of pixels may be 128. Processor may down-sample the high pixel count image to convert the 256 pixels into 128 pixels. In some embodiments, processor may be configured to perform downsampling on data. Downsampling, also known as decimation, may include removing every Nth entry in a sequence of samples, all but every Nth entry, or the like, which is a process known as “compression,” and may be performed, for instance by an N-sample compressor implemented using hardware or software. Anti-aliasing and/or anti-imaging filters, and/or low-pass filters, may be used to clean up side-effects of compression.

Further referring to FIG. 6, feature selection includes narrowing and/or filtering training data to exclude features and/or elements, or training data including such elements, that are not relevant to a purpose for which a trained machine-learning model and/or algorithm is being trained, and/or collection of features and/or elements, or training data including such elements, on the basis of relevance or utility for an intended task or purpose for a trained machine-learning model and/or algorithm is being trained. Feature selection may be implemented, without limitation, using any process described in this disclosure, including without limitation using training data classifiers, exclusion of outliers, or the like.

With continued reference to FIG. 6, feature scaling may include, without limitation, normalization of data entries, which may be accomplished by dividing numerical fields by norms thereof, for instance as performed for vector normalization. Feature scaling may include absolute maximum scaling, wherein each quantitative datum is divided by the maximum absolute value of all quantitative data of a set or subset of quantitative data. Feature scaling may include min-max scaling, in which each value X has a minimum value Xₘᵢₙ in a set or subset of values subtracted therefrom, with the result divided by the range of the values, give maximum value in the set or subset Xₘₐₓ:

$${X}_{n e w} = \frac{X - {X}_{min}}{{X}_{max} - {X}_{min}} .$$

Feature scaling may include mean normalization, which involves use of a mean value of a set and/or subset of values, Xₘₑₐₙ with maximum and minimum values:

$${X}_{n e w} = \frac{X - {X}_{m e a n}}{{X}_{max} - {X}_{min}} .$$

Feature scaling may include standardization, where a difference between X and Xₘₑₐₙ is divided by a standard deviation σ of a set or subset of values:

$${X}_{n e w} = \frac{X - {X}_{m e a n}}{σ} .$$

Scaling may be performed using a median value of a set or subset X_{median} and/or interquartile range (IQR), which represents the difference between the 25th percentile value and the 50^{th} percentile value (or closest values thereto by a rounding protocol), such as:

$${X}_{n e w} = \frac{X - {X}_{median}}{IQR} .$$

Persons skilled in the art, upon reviewing the entirety of this disclosure, will be aware of various alternative or additional approaches that may be used for feature scaling.

Further referring to FIG. 6, computing device, processor, and/or module may be configured to perform one or more processes of data augmentation. “Data augmentation” as used in this disclosure is addition of data to a training set using elements and/or entries already in the dataset. Data augmentation may be accomplished, without limitation, using interpolation, generation of modified copies of existing entries and/or examples, and/or one or more generative AI processes, for instance using deep neural networks and/or generative adversarial networks; generative processes may be referred to alternatively in this context as “data synthesis” and as creating “synthetic data.” Augmentation may include performing one or more transformations on data, such as geometric, color space, affine, brightness, cropping, and/or contrast transformations of images.

With continued reference to FIG. 6, machine-learning module 600 may be configured to perform a lazy-learning process 620 and/or protocol, which may alternatively be referred to as a “lazy loading” or “call-when-needed” process and/or protocol, may be a process whereby machine-learning is conducted upon receipt of an input to be converted to an output, by combining the input and training set to derive the algorithm to be used to produce the output on demand. For instance, an initial set of simulations may be performed to cover an initial heuristic and/or “first guess” at an output and/or relationship. As a non-limiting example, an initial heuristic may include a ranking of associations between inputs and elements of training data 604. Heuristic may include selecting some number of highest-ranking associations and/or training data 604 elements. Lazy learning may implement any suitable lazy learning algorithm, including without limitation a K-nearest neighbors algorithm, a lazy naïve Bayes algorithm, or the like; persons skilled in the art, upon reviewing the entirety of this disclosure, will be aware of various lazy-learning algorithms that may be applied to generate outputs as described in this disclosure, including without limitation lazy learning applications of machine-learning algorithms as described in further detail below.

Alternatively or additionally, and with continued reference to FIG. 6, machine-learning processes as described in this disclosure may be used to generate machine-learning models 624. A “machine-learning model,” as used in this disclosure, is a data structure representing and/or instantiating a mathematical and/or algorithmic representation of a relationship between inputs and outputs, as generated using any machine-learning process including without limitation any process as described above, and stored in memory; an input is submitted to a machine-learning model 624 once created, which generates an output based on the relationship that was derived. For instance, and without limitation, a linear regression model, generated using a linear regression algorithm, may compute a linear combination of input data using coefficients derived during machine-learning processes to calculate an output datum. As a further non-limiting example, a machine-learning model 624 may be generated by creating an artificial neural network, such as a convolutional neural network comprising an input layer of nodes, one or more intermediate layers, and an output layer of nodes. Connections between nodes may be created via the process of “training” the network, in which elements from a training data 604 set are applied to the input nodes, a suitable training algorithm (such as Levenberg-Marquardt, conjugate gradient, simulated annealing, or other algorithms) is then used to adjust the connections and weights between nodes in adjacent layers of the neural network to produce the desired values at the output nodes. This process is sometimes referred to as deep learning.

With continued reference to FIG. 6, machine-learning algorithms may include at least a supervised machine-learning process 628. At least a supervised machine-learning process 628, as defined herein, include algorithms that receive a training set relating a number of inputs to a number of outputs, and seek to generate one or more data structures representing and/or instantiating one or more mathematical relations relating inputs to outputs, where each of the one or more mathematical relations is optimal according to some criterion specified to the algorithm using some scoring function. For instance, a supervised learning algorithm may include representative part model 120, part feature 136, building part 160, part progress class label 144, region class 162, design progress state 164, design reference 140, design problem 146, user query 182, and the like as described above as inputs, part feature 136, building part 160, part progress class label 144, region class 162, design progress state 164, design reference 140, design problem 146, design solution 148, user prompt 152, component 116, and the like as outputs, and a scoring function representing a desired form of relationship to be detected between inputs and outputs; scoring function may, for instance, seek to maximize the probability that a given input and/or combination of elements inputs is associated with a given output to minimize the probability that a given input is not associated with a given output. Scoring function may be expressed as a risk function representing an “expected loss” of an algorithm relating inputs to outputs, where loss is computed as an error function representing a degree to which a prediction generated by the relation is incorrect when compared to a given input-output pair provided in training data 604. Persons skilled in the art, upon reviewing the entirety of this disclosure, will be aware of various possible variations of at least a supervised machine-learning process 628 that may be used to determine relation between inputs and outputs. Supervised machine-learning processes may include classification algorithms as defined above.

With further reference to FIG. 6, training a supervised machine-learning process may include, without limitation, iteratively updating coefficients, biases, weights based on an error function, expected loss, and/or risk function. For instance, an output generated by a supervised machine-learning model using an input example in a training example may be compared to an output example from the training example; an error function may be generated based on the comparison, which may include any error function suitable for use with any machine-learning algorithm described in this disclosure, including a square of a difference between one or more sets of compared values or the like. Such an error function may be used in turn to update one or more weights, biases, coefficients, or other parameters of a machine-learning model through any suitable process including without limitation gradient descent processes, least-squares processes, and/or other processes described in this disclosure. This may be done iteratively and/or recursively to gradually tune such weights, biases, coefficients, or other parameters. Updating may be performed, in neural networks, using one or more back-propagation algorithms. Iterative and/or recursive updates to weights, biases, coefficients, or other parameters as described above may be performed until currently available training data is exhausted and/or until a convergence test is passed, where a “convergence test” is a test for a condition selected as indicating that a model and/or weights, biases, coefficients, or other parameters thereof has reached a degree of accuracy. A convergence test may, for instance, compare a difference between two or more successive errors or error function values, where differences below a threshold amount may be taken to indicate convergence. Alternatively or additionally, one or more errors and/or error function values evaluated in training iterations may be compared to a threshold.

With continued reference to FIG. 6, a computing device, processor, and/or module may be configured to perform method, method step, sequence of method steps and/or algorithm described in reference to this figure, in any order and with any degree of repetition. For instance, a computing device, processor, and/or module may be configured to perform a single step, sequence and/or algorithm repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. A computing device, processor, and/or module may perform any step, sequence of steps, or algorithm in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

Further referring to FIG. 6, machine-learning processes may include at least an unsupervised machine-learning processes 632. An unsupervised machine-learning process, as used herein, is a process that derives inferences in datasets without regard to labels; as a result, an unsupervised machine-learning process may be free to discover any structure, relationship, and/or correlation provided in the data. Unsupervised processes 632 may not require a response variable; unsupervised processes 632 may be used to find interesting patterns and/or inferences between variables, to determine a degree of correlation between two or more variables, or the like.

With continued reference to FIG. 6, machine-learning module 600 may be designed and configured to create a machine-learning model 624 using techniques for development of linear regression models. Linear regression models may include ordinary least squares regression, which aims to minimize the square of the difference between predicted outcomes and actual outcomes according to an appropriate norm for measuring such a difference (e.g. a vector-space distance norm); coefficients of the resulting linear equation may be modified to improve minimization. Linear regression models may include ridge regression methods, where the function to be minimized includes the least-squares function plus term multiplying the square of each coefficient by a scalar amount to penalize large coefficients. Linear regression models may include least absolute shrinkage and selection operator (LASSO) models, in which ridge regression is combined with multiplying the least-squares term by a factor of 1 divided by double the number of samples. Linear regression models may include a multi-task lasso model wherein the norm applied in the least-squares term of the lasso model is the Frobenius norm amounting to the square root of the sum of squares of all terms. Linear regression models may include the clastic net model, a multi-task elastic net model, a least angle regression model, a LARS lasso model, an orthogonal matching pursuit model, a Bayesian regression model, a logistic regression model, a stochastic gradient descent model, a perceptron model, a passive aggressive algorithm, a robustness regression model, a Huber regression model, or any other suitable model that may occur to persons skilled in the art upon reviewing the entirety of this disclosure. Linear regression models may be generalized in an embodiment to polynomial regression models, whereby a polynomial equation (e.g. a quadratic, cubic or higher-order equation) providing a best predicted output/actual output fit is sought; similar methods to those described above may be applied to minimize error functions, as will be apparent to persons skilled in the art upon reviewing the entirety of this disclosure.

With continued reference to FIG. 6, machine-learning algorithms may include, without limitation, linear discriminant analysis. Machine-learning algorithm may include quadratic discriminant analysis. Machine-learning algorithms may include kernel ridge regression. Machine-learning algorithms may include support vector machines, including without limitation support vector classification-based regression processes. Machine-learning algorithms may include stochastic gradient descent algorithms, including classification and regression algorithms based on stochastic gradient descent. Machine-learning algorithms may include nearest neighbors algorithms. Machine-learning algorithms may include various forms of latent space regularization such as variational regularization. Machine-learning algorithms may include Gaussian processes such as Gaussian Process Regression. Machine-learning algorithms may include cross-decomposition algorithms, including partial least squares and/or canonical correlation analysis. Machine-learning algorithms may include naïve Bayes methods. Machine-learning algorithms may include algorithms based on decision trees, such as decision tree classification or regression algorithms. Machine-learning algorithms may include ensemble methods such as bagging meta-estimator, forest of randomized trees, AdaBoost, gradient tree boosting, and/or voting classifier methods. Machine-learning algorithms may include neural net algorithms, including convolutional neural net processes.

With continued reference to FIG. 6, a machine-learning model and/or process may be deployed or instantiated by incorporation into a program, apparatus, system and/or module. For instance, and without limitation, a machine-learning model, neural network, and/or some or all parameters thereof may be stored and/or deployed in any memory or circuitry. Parameters such as coefficients, weights, and/or biases may be stored as circuit-based constants, such as arrays of wires and/or binary inputs and/or outputs set at logic “1” and “0” voltage levels in a logic circuit to represent a number according to any suitable encoding system including twos complement or the like or may be stored in any volatile and/or non-volatile memory. Similarly, mathematical operations and input and/or output of data to or from models, neural network layers, or the like may be instantiated in hardware circuitry and/or in the form of instructions in firmware, machine-code such as binary operation code instructions, assembly language, or any higher-order programming language. Any technology for hardware and/or software instantiation of memory, instructions, data structures, and/or algorithms may be used to instantiate a machine-learning process and/or model, including without limitation any combination of production and/or configuration of non-reconfigurable hardware elements, circuits, and/or modules such as without limitation ASICs, production and/or configuration of reconfigurable hardware elements, circuits, and/or modules such as without limitation FPGAs, production and/or of non-reconfigurable and/or configuration non-rewritable memory elements, circuits, and/or modules such as without limitation non-rewritable ROM, production and/or configuration of reconfigurable and/or rewritable memory elements, circuits, and/or modules such as without limitation rewritable ROM or other memory technology described in this disclosure, and/or production and/or configuration of any computing device and/or component thereof as described in this disclosure. Such deployed and/or instantiated machine-learning model and/or algorithm may receive inputs from any other process, module, and/or component described in this disclosure, and produce outputs to any other process, module, and/or component described in this disclosure.

With continued reference to FIG. 6, any process of training, retraining, deployment, and/or instantiation of any machine-learning model and/or algorithm may be performed and/or repeated after an initial deployment and/or instantiation to correct, refine, and/or improve the machine-learning model and/or algorithm. Such retraining, deployment, and/or instantiation may be performed as a periodic or regular process, such as retraining, deployment, and/or instantiation at regular elapsed time periods, after some measure of volume such as a number of bytes or other measures of data processed, a number of uses or performances of processes described in this disclosure, or the like, and/or according to a software, firmware, or other update schedule. Alternatively or additionally, retraining, deployment, and/or instantiation may be event-based, and may be triggered, without limitation, by user inputs indicating sub-optimal or otherwise problematic performance and/or by automated field testing and/or auditing processes, which may compare outputs of machine-learning models and/or algorithms, and/or errors and/or error functions thereof, to any thresholds, convergence tests, or the like, and/or may compare outputs of processes described herein to similar thresholds, convergence tests or the like. Event-based retraining, deployment, and/or instantiation may alternatively or additionally be triggered by receipt and/or generation of one or more new training examples; a number of new training examples may be compared to a preconfigured threshold, where exceeding the preconfigured threshold may trigger retraining, deployment, and/or instantiation.

With continued reference to FIG. 6, retraining and/or additional training may be performed using any process for training described above, using any currently or previously deployed version of a machine-learning model and/or algorithm as a starting point. Training data for retraining may be collected, preconditioned, sorted, classified, sanitized or otherwise processed according to any process described in this disclosure. Training data may include, without limitation, training examples including inputs and correlated outputs used, received, and/or generated from any version of any system, module, machine-learning model or algorithm, apparatus, and/or method described in this disclosure; such examples may be modified and/or labeled according to user feedback or other processes to indicate desired results, and/or may have actual or measured results from a process being modeled and/or predicted by system, module, machine-learning model or algorithm, apparatus, and/or method as “desired” results to be compared to outputs for training processes as described above.

Redeployment may be performed using any reconfiguring and/or rewriting of reconfigurable and/or rewritable circuit and/or memory elements; alternatively, redeployment may be performed by production of new hardware and/or software components, circuits, instructions, or the like, which may be added to and/or may replace existing hardware and/or software components, circuits, instructions, or the like.

Further referring to FIG. 6, one or more processes or algorithms described above may be performed by at least a dedicated hardware unit 636. A “dedicated hardware unit,” for the purposes of this figure, is a hardware component, circuit, or the like, aside from a principal control circuit and/or processor performing method steps as described in this disclosure, that is specifically designated or selected to perform one or more specific tasks and/or processes described in reference to this figure, such as without limitation preconditioning and/or sanitization of training data and/or training a machine-learning algorithm and/or model. A dedicated hardware unit 636 may include, without limitation, a hardware unit that can perform iterative or massed calculations, such as matrix-based calculations to update or tune parameters, weights, coefficients, and/or biases of machine-learning models and/or neural networks, efficiently using pipelining, parallel processing, or the like; such a hardware unit may be optimized for such processes by, for instance, including dedicated circuitry for matrix and/or signal processing operations that includes, e.g., multiple arithmetic and/or logical circuit units such as multipliers and/or adders that can act simultaneously and/or in parallel or the like. Such dedicated hardware units 636 may include, without limitation, graphical processing units (GPUs), dedicated signal processing modules, FPGA or other reconfigurable hardware that has been configured to instantiate parallel processing units for one or more specific tasks, or the like, A computing device, processor, apparatus, or module may be configured to instruct one or more dedicated hardware units 636 to perform one or more operations described herein, such as evaluation of model and/or algorithm outputs, one-time or iterative updates to parameters, coefficients, weights, and/or biases, and/or any other operations such as vector and/or matrix operations as described in this disclosure.

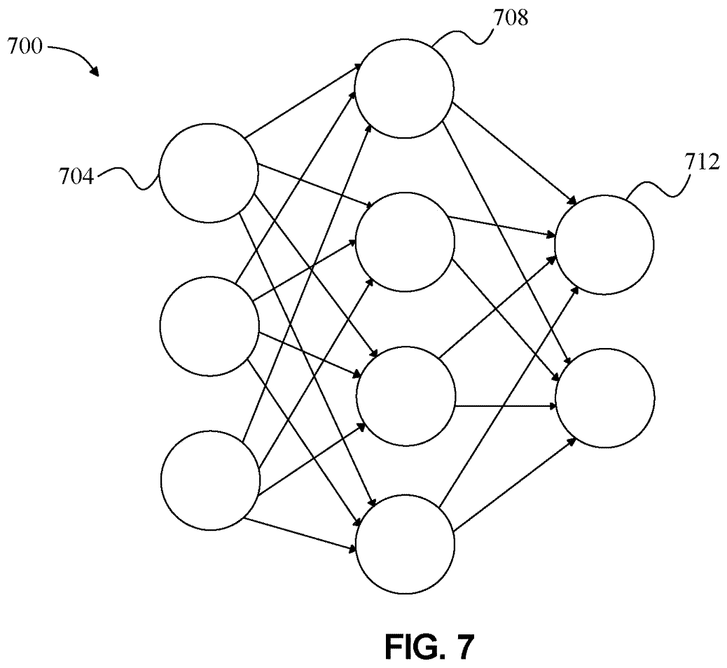

Referring now to FIG. 7 an exemplary embodiment of neural network 700 is illustrated. A neural network 700 also known as an artificial neural network, is a network of “nodes,” or data structures having one or more inputs, one or more outputs, and a function determining outputs based on inputs. Such nodes may be organized in a network, such as without limitation a convolutional neural network, including an input layer of nodes 704, one or more intermediate layers 708, and an output layer of nodes 712. Connections between nodes may be created via the process of “training” the network, in which elements from a training dataset are applied to the input nodes, a suitable training algorithm (such as Levenberg-Marquardt, conjugate gradient, simulated annealing, or other algorithms) is then used to adjust the connections and weights between nodes in adjacent layers of the neural network to produce the desired values at the output nodes. This process is sometimes referred to as deep learning. Connections may run solely from input nodes toward output nodes in a “feed-forward” network, or may feed outputs of one layer back to inputs of the same or a different layer in a “recurrent network.” As a further non-limiting example, a neural network may include a convolutional neural network comprising an input layer of nodes, one or more intermediate layers, and an output layer of nodes. A “convolutional neural network,” as used in this disclosure, is a neural network in which at least one hidden layer is a convolutional layer that convolves inputs to that layer with a subset of inputs known as a “kernel,” along with one or more additional layers such as pooling layers, fully connected layers, and the like.

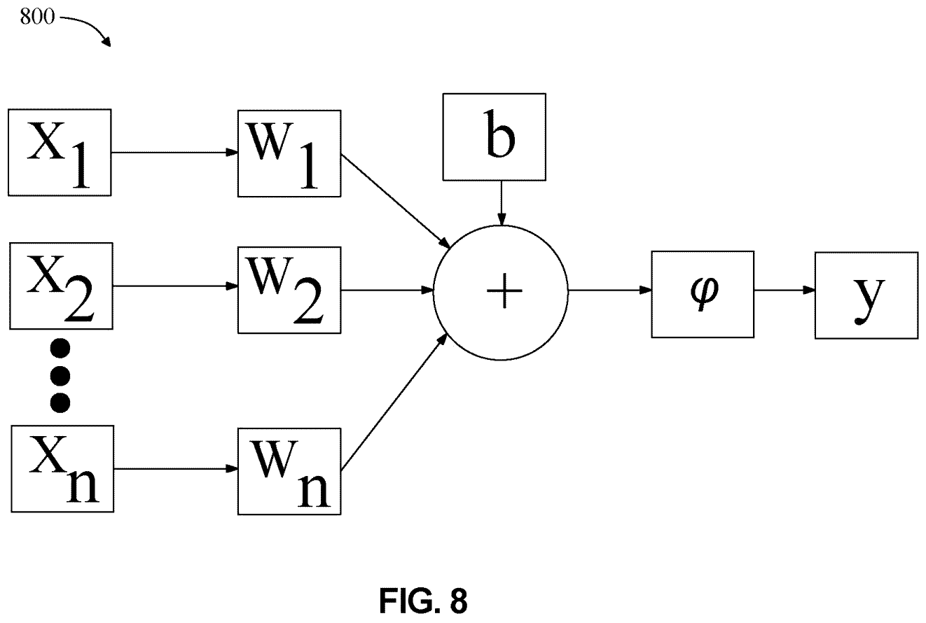

Referring now to FIG. 8, an exemplary embodiment 800 of a node of a neural network is illustrated. A node may include, without limitation, a plurality of inputs x; that may receive numerical values from inputs to a neural network containing the node and/or from other nodes. Node may perform a weighted sum of inputs using weights w; that are multiplied by respective inputs xᵢ. Additionally or alternatively, a bias b may be added to the weighted sum of the inputs such that an offset is added to each unit in the neural network layer that is independent of the input to the layer. The weighted sum may then be input into a function φ, which may generate one or more outputs y. Weight w; applied to an input x; may indicate whether the input is “excitatory,” indicating that it has strong influence on the one or more outputs y, for instance by the corresponding weight having a large numerical value, and/or a “inhibitory,” indicating it has a weak effect influence on the one more inputs y, for instance by the corresponding weight having a small numerical value. The values of weights wᵢ may be determined by training a neural network using training data, which may be performed using any suitable process as described above.

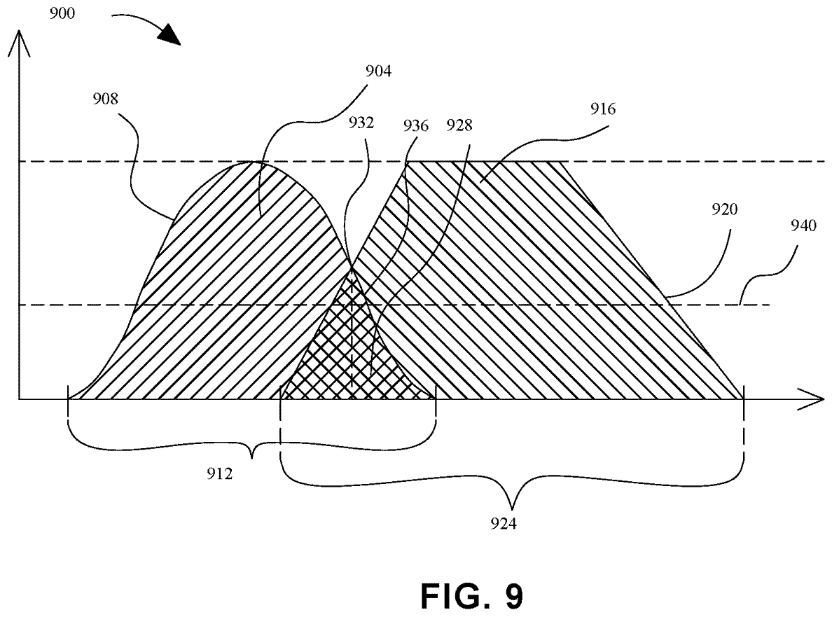

Referring to FIG. 9, an exemplary embodiment of fuzzy set comparison 900 is illustrated. A first fuzzy set 904 may be represented, without limitation, according to a first membership function 908 representing a probability that an input falling on a first range of values 912 is a member of the first fuzzy set 904, where the first membership function 908 has values on a range of probabilities such as without limitation the interval [0,1], and an area beneath the first membership function 908 may represent a set of values within first fuzzy set 904. Although first range of values 912 is illustrated for clarity in this exemplary depiction as a range on a single number line or axis, first range of values 912 may be defined on two or more dimensions, representing, for instance, a Cartesian product between a plurality of ranges, curves, axes, spaces, dimensions, or the like. First membership function 908 may include any suitable function mapping first range of values 912 to a probability interval, including without limitation a triangular function defined by two linear elements such as line segments or planes that intersect at or below the top of the probability interval. As a non-limiting example, triangular membership function may be defined as:

$$y ( x , a , b , c ) = \{ \begin{matrix}0 , for x > c and X < a \\ \frac{x - a}{b - a} , for a \leq x < b \\ \frac{c - x}{c - b} , if b < x \leq c\end{matrix}$$

a trapezoidal membership function may be defined as:

$$y ( x , a , b , c , d ) = max ( min ( \frac{x - a}{b - a} , 1 , \frac{d - x}{d - c} ) , 0 )$$

a sigmoidal function may be defined as:

$$y ( x , a , c ) = \frac{1}{1 - {e}^{- a ( x - c )}}$$

a Gaussian membership function may be defined as:

$$y ( x , c , σ ) = {e}^{- \frac{1}{2} {( \frac{x - c}{σ} )}^{2}}$$

and a bell membership function may be defined as:

$$y ( x , a , b , c , ) = {[ 1 + {\vert \frac{x - c}{a} \vert}^{2 b} ]}^{- 1}$$

Persons skilled in the art, upon reviewing the entirety of this disclosure, will be aware of various alternative or additional membership functions that may be used consistently with this disclosure.

With continued reference to FIG. 9, first fuzzy set 904 may represent any value or combination of values as described above, including output from one or more machine-learning models. A second fuzzy set 916, which may represent any value which may be represented by first fuzzy set 904, may be defined by a second membership function 920 on a second range 924; second range 924 may be identical and/or overlap with first range of values 912 and/or may be combined with first range via Cartesian product or the like to generate a mapping permitting evaluation overlap of first fuzzy set 904 and second fuzzy set 916. Where first fuzzy set 904 and second fuzzy set 916 have a region 928 that overlaps, first membership function 908 and second membership function 920 may intersect at a point 932 representing a probability, as defined on probability interval, of a match between first fuzzy set 904 and second fuzzy set 916. Alternatively or additionally, a single value of first and/or second fuzzy set may be located at a locus 936 on first range of values 912 and/or second range 924, where a probability of membership may be taken by evaluation of first membership function 908 and/or second membership function 920 at that range point. A probability at 928 and/or 932 may be compared to a threshold 940 to determine whether a positive match is indicated. Threshold 940 may, in a non-limiting example, represent a degree of match between first fuzzy set 904 and second fuzzy set 916, and/or single values therein with each other or with either set, which is sufficient for purposes of the matching process; for instance, threshold may indicate a sufficient degree of overlap between an output from one or more machine-learning models and/or design problem 146 and a predetermined class, for combination to occur as described above. Alternatively or additionally, each threshold may be tuned by a machine-learning and/or statistical process, for instance and without limitation as described in further detail below.

Further referring to FIG. 9, in an embodiment, a degree of match between fuzzy sets may be used to classify a design problem 146 based on input data such as the representative part model 120. For instance, if a design problem has a fuzzy set matching a representative part model fuzzy set by having a degree of overlap exceeding a threshold, processor 104 may classify the design problem 146 as belonging to the representative part model. Where multiple fuzzy matches are performed, degrees of match for each respective fuzzy set may be computed and aggregated through, for instance, addition, averaging, or the like, to determine an overall degree of match.

With continued reference to FIG. 9, in an embodiment, a design problem may be compared to multiple representative part model fuzzy sets. For instance, design problem may be represented by a fuzzy set that is compared to each of the multiple representative part model fuzzy sets; and a degree of overlap exceeding a threshold between the design problem fuzzy set and any of the multiple representative part model fuzzy sets may cause processor 104 to classify the design problem as belonging to representative part model. For instance, in one embodiment there may be two representative part model fuzzy sets, representing respectively representative part model and representative part model. First representative part model may have a first fuzzy set; Second representative part model may have a second fuzzy set; and design problem may have a design problem fuzzy set. Processor 104, for example, may compare a design problem fuzzy set with each of representative part model fuzzy set and representative part model fuzzy set, as described above, and classify a design problem to either, both, or neither of representative part model or representative part model. Machine-learning methods as described throughout may, in a non-limiting example, generate coefficients used in fuzzy set equations as described above, such as without limitation x, c, and σ of a Gaussian set as described above, as outputs of machine-learning methods. Likewise, design problem may be used indirectly to determine a fuzzy set, as design problem fuzzy set may be derived from outputs of one or more machine-learning models that take the design problem directly or indirectly as inputs.

With continued reference to FIG. 9, a computing device may use a logic comparison program, such as, but not limited to, a fuzzy logic model to determine a score. A score may include, but is not limited to, amateur, average, knowledgeable, superior, and the like; each such score may be represented as a value for a linguistic variable representing score, or in other words a fuzzy set as described above that corresponds to a degree of similarity as calculated using any statistical, machine-learning, or other method that may occur to a person skilled in the art upon reviewing the entirety of this disclosure. In other words, a given element of design problem may have a first non-zero value for membership in a first linguistic variable value and a second non-zero value for membership in a second linguistic variable value. In some embodiments, determining a score may include using a linear regression model. A linear regression model may include a machine-learning model. A linear regression model may be configured to map data of design problem, such as various elements in the representative part model, to one or more scores. A linear regression model may be trained using previously categorized elements in the representative part model. In some embodiments, determining a score of design problem may include using a score classification model. A score classification model may be configured to input collected data and cluster data to a centroid based on, but not limited to, frequency of appearance, and the like. Centroids may include scores assigned to them such that elements of the representative part model may each be assigned a score. In some embodiments, and score classification model may include a K-means clustering model. In some embodiments, and score classification model may include a particle swarm optimization model. In some embodiments, determining a score of design problem may include using a fuzzy inference engine. A fuzzy inference engine may be configured to map one or more design problem data elements using fuzzy logic. In some embodiments, a plurality of entity assessment devices may be arranged by a logic comparison program into score arrangements. An “score arrangement” as used in this disclosure is any grouping of objects and/or data based on skill level and/or output score. This step may be implemented as described above in FIGS. 1-7. Membership function coefficients and/or constants as described above may be tuned according to classification and/or clustering algorithms. For instance, and without limitation, a clustering algorithm may determine a Gaussian or other distribution of questions about a centroid corresponding to a given score level, and an iterative or other method may be used to find a membership function, for any membership function type as described above, that minimizes an average error from the statistically determined distribution, such that, for instance, a triangular or Gaussian membership function about a centroid representing a center of the distribution that most closely matches the distribution. Error functions to be minimized, and/or methods of minimization, may be performed without limitation according to any error function and/or error function minimization process and/or method as described in this disclosure.

Further referring to FIG. 9, an inference engine may be implemented according to input and/or output membership functions and/or linguistic variables. For instance, a first linguistic variable may represent a first measurable value pertaining to a degree of similarity, while a second membership function may indicate a degree of similarity of a subject thereof, or another measurable value pertaining to design problem. Continuing the example, an output linguistic variable may represent, without limitation, a score value. An inference engine may combine rules, such as: “if the difficulty level is ‘hard’ and the popularity level is ‘high’, the question score is ‘high’”—the degree to which a given input function membership matches a given rule may be determined by a triangular norm or “T-norm” of the rule or output membership function with the input membership function, such as min (a, b), product of a and b, drastic product of a and b, Hamacher product of a and b, or the like, satisfying the rules of commutativity (T(a, b)=T(b, a)), monotonicity: (T(a, b)≤T(c, d) if a≤c and b≤d), (associativity: T(a, T(b, c))=T (T(a, b), c)), and the requirement that the number 1 acts as an identity element. Combinations of rules (“and” or “or” combination of rule membership determinations) may be performed using any T-conorm, as represented by an inverted T symbol or “⊥,” such as max (a, b), probabilistic sum of a and b (a+b−a*b), bounded sum, and/or drastic T-conorm; any T-conorm may be used that satisfies the properties of commutativity: ⊥(a, b)=⊥(b, a), monotonicity: ⊥(a, b)≤⊥(c, d) if a≤c and b≤d, associativity: ⊥(a, ⊥(b, c))=⊥(⊥(a, b), c), and identity element of 0. Alternatively or additionally T-conorm may be approximated by sum, as in a “product-sum” inference engine in which T-norm is product and T-conorm is sum. A final output score or other fuzzy inference output may be determined from an output membership function as described above using any suitable defuzzification process, including without limitation Mean of Max defuzzification, Centroid of Area/Center of Gravity defuzzification, Center Average defuzzification, Bisector of Area defuzzification, or the like. Alternatively or additionally, output rules may be replaced with functions according to the Takagi-Sugeno-King (TSK) fuzzy model.

Further referring to FIG. 9, design problem to be used may be selected by user selection, and/or by selection of a distribution of output scores, such as 30% hard/expert, 40% moderate average, and 30% easy/beginner levels or the like.

Referring to FIG. 10, a chatbot system 1000 is schematically illustrated. According to some embodiments, a user interface 1004 may be communicative with a computing device 1008 that is configured to operate a chatbot. In some cases, user interface 1004 may be local to computing device 1008. Alternatively or additionally, in some cases, user interface 1004 may remote to computing device 1008 and communicative with the computing device 1008, by way of one or more networks, such as without limitation the internet. Alternatively or additionally, user interface 1004 may communicate with computing device 1008 using telephonic devices and networks, such as without limitation fax machines, short message service (SMS), or multimedia message service (MMS). Computing device 1008 disclosed herein may be consistent with remote device 124. Commonly, user interface 1004 communicates with computing device 1008 using text-based communication, for example without limitation using a character encoding protocol, such as American Standard for Information Interchange (ASCII). Typically, a user interface 1004 conversationally interfaces a chatbot, by way of at least a submission 1012, from the user interface 1004 to the chatbot, and a response 1016, from the chatbot to the user interface 1004. In many cases, one or both of submission 1012 and response 1016 are text-based communication. Alternatively or additionally, in some cases, one or both of submission 1012 and response 1016 are audio-based communication.

Continuing in reference to FIG. 10, a submission 1012 once received by computing device 1008 operating a chatbot, may be processed by a processor. In some embodiments, processor processes a submission 1012 using one or more of keyword recognition, pattern matching, and natural language processing. In some embodiments, processor employs real-time learning with evolutionary algorithms. In some cases, processor may retrieve a pre-prepared response from at least a storage component 1020, based upon submission 1012. Alternatively or additionally, in some embodiments, processor communicates a response 1016 without first receiving a submission 1012, thereby initiating conversation. In some cases, processor communicates an inquiry to user interface 1004; and the processor is configured to process an answer to the inquiry in a following submission 1012 from the user interface 1004. In some cases, an answer to an inquiry present within a submission 1012 from a computing device 1008 may be used by computing device 1008 as an input to another function.

With continued reference to FIG. 10, a chatbot may be configured to provide a user with a plurality of options as an input into the chatbot. Chatbot entries may include multiple choice, short answer response, true or false responses, and the like. A user may decide on what type of chatbot entries are appropriate. In some embodiments, the chatbot may be configured to allow the user to input a freeform response into the chatbot. The chatbot may then use a decision tree, data base, or other data structure to respond to the users entry into the chatbot as a function of a chatbot input. As used in the current disclosure, “chatbot input” is any response that a user inputs into a chatbot as a response to a prompt or question. As a non-limiting example, chatbot input may include a user prompt 152.

With continuing reference to FIG. 10, computing device 1008 may be configured to the respond to a chatbot input using a decision tree. A “decision tree,” as used in this disclosure, is a data structure that represents and combines one or more determinations or other computations based on and/or concerning data provided thereto, as well as earlier such determinations or calculations, as nodes of a tree data structure where inputs of some nodes are connected to outputs of others. Decision tree may have at least a root node, or node that receives data input to the decision tree, corresponding to at least a candidate input into a chatbot. Decision tree has at least a terminal node, which may alternatively or additionally be referred to herein as a “leaf node,” corresponding to at least an exit indication; in other words, decision and/or determinations produced by decision tree may be output at the at least a terminal node. Decision tree may include one or more internal nodes, defined as nodes connecting outputs of root nodes to inputs of terminal nodes. Computing device 1008 may generate two or more decision trees, which may overlap; for instance, a root node of one tree may connect to and/or receive output from one or more terminal nodes of another tree, intermediate nodes of one tree may be shared with another tree, or the like.

With continued reference to FIG. 10, computing device 1008 may build decision tree by following relational identification; for example, relational indication may specify that a first rule module receives an input from at least a second rule module and generates an output to at least a third rule module, and so forth, which may indicate to computing device 1008 an in which such rule modules will be placed in decision tree. Building decision tree may include recursively performing mapping of execution results output by one tree and/or subtree to root nodes of another tree and/or subtree, for instance by using such execution results as execution parameters of a subtree. In this manner, computing device 1008 may generate connections and/or combinations of one or more trees to one another to define overlaps and/or combinations into larger trees and/or combinations thereof. Such connections and/or combinations may be displayed by visual interface to user, for instance in first view, to enable viewing, editing, selection, and/or deletion by user; connections and/or combinations generated thereby may be highlighted, for instance using a different color, a label, and/or other form of emphasis aiding in identification by a user. In some embodiments, subtrees, previously constructed trees, and/or entire data structures may be represented and/or converted to rule modules, with graphical models representing them, and which may then be used in further iterations or steps of generation of decision tree and/or data structure. Alternatively or additionally subtrees, previously constructed trees, and/or entire data structures may be converted to APIs to interface with further iterations or steps of methods as described in this disclosure. As a further example, such subtrees, previously constructed trees, and/or entire data structures may become remote resources to which further iterations or steps of data structures and/or decision trees may transmit data and from which further iterations or steps of generation of data structure receive data, for instance as part of a decision in a given decision tree node.

With continued reference to FIG. 10, decision tree may incorporate one or more manually entered or otherwise provided decision criteria. Decision tree may incorporate one or more decision criteria using an application programmer interface (API). Decision tree may establish a link to a remote decision module, device, system, or the like. Decision tree may perform one or more database lookups and/or look-up table lookups. Decision tree may include at least a decision calculation module, which may be imported via an API, by incorporation of a program module in source code, executable, or other form, and/or linked to a given node by establishing a communication interface with one or more exterior processes, programs, systems, remote devices, or the like; for instance, where a user operating system has a previously existent calculation and/or decision engine configured to make a decision corresponding to a given node, for instance and without limitation using one or more elements of domain knowledge, by receiving an input and producing an output representing a decision, a node may be configured to provide data to the input and receive the output representing the decision, based upon which the node may perform its decision.

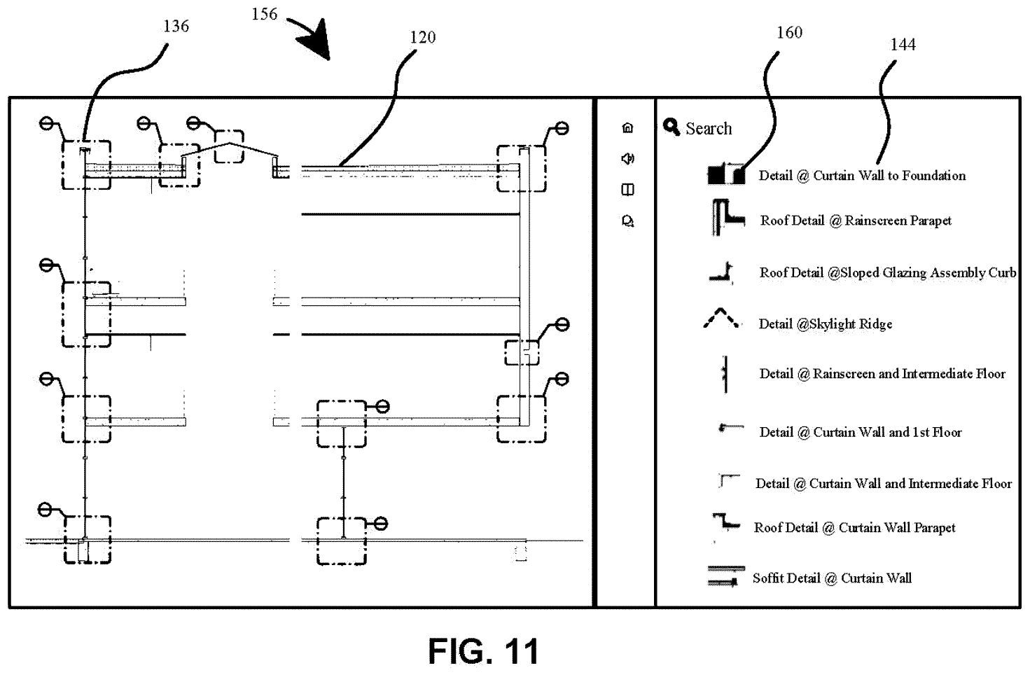

Referring now to FIG. 11, an exemplary user interface 156 displaying a plurality of part features 136 of a representative part model 120 and a plurality of part progress class labels 144 of a plurality of building parts 160 is illustrated. In some embodiments, processor 104 may generate user interface 156 displaying representative part model 120 on a remote device 124. In some embodiments, processor 104 may generate user interface 156 displaying part features 136 detected from representative part model 120 by flagging, highlighting, commenting, and the like the part features 136 as shown in FIG. 11. In a non-limiting example, user 128 may manipulate GUI to interact with part features 136. For example, and without limitation, user 128 may click a flagged part features 136 to retrieve information related to part features 136; for instance, region class 162, design progress state 164, part progress class label 144, semantic information, and the like. In some embodiments, processor 104 may generate user interface 156 displaying part progress class labels 144 of a plurality of building parts 160 as shown in FIG. 11 or representative part model 120. In a non-limiting example, GUI may display a drawing of building parts 160 and related part progress class label 144 and user 128 may manipulate GUI to interact with building parts 160 and related part progress class label 144 to retrieve information related to them; for instance, region class 162, design progress state 164, part progress class label 144, semantic information, design problem 146, design solution 148, design assist datum 178, and the like.

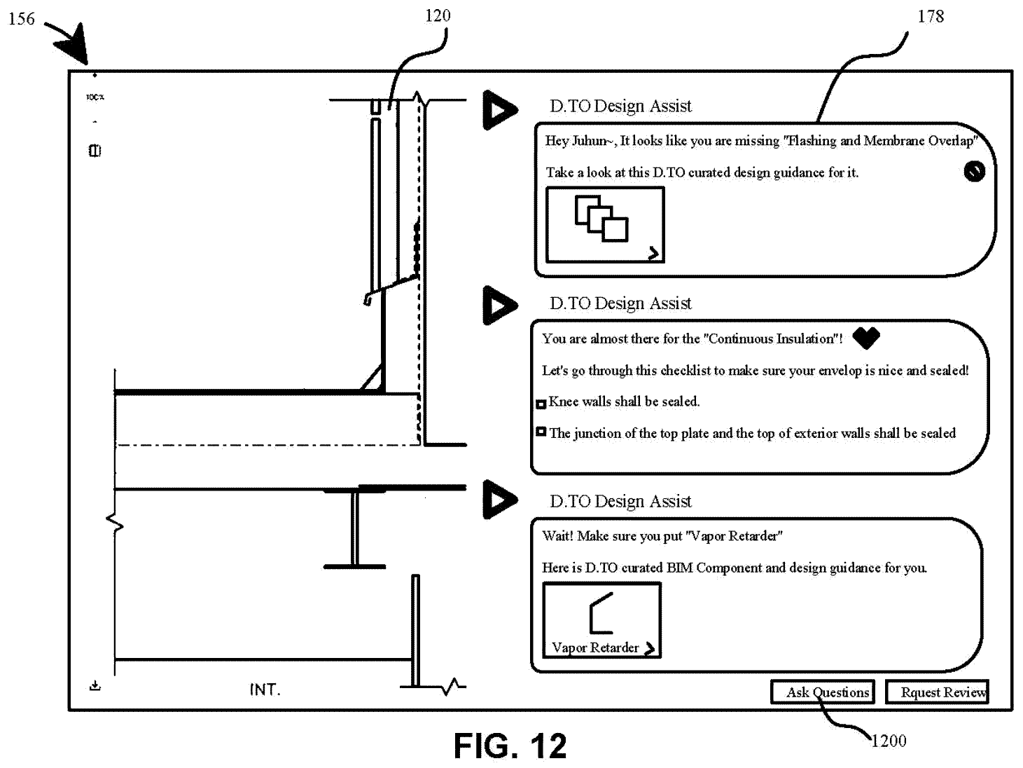

Referring now to FIG. 12, an exemplary user interface 156 displaying a representative part model 120 and a plurality of design assist datums 178 is illustrated. In some embodiments, processor 104 may generate user interface 156 displaying representative part model 120, design assist datum 178, user prompt 152, and the like on a remote device 124. In some embodiments, design assist datum 178 may include a reminder, notification, encouragement for a user 128 to improve representative part model 120, and the like. For example, and without limitation, design assist datum 178 may remind a user 128 related to design problem 146 detected from representative part model 120 and design solution 148 generated to resolve design problem 146. As shown in FIG. 12, design assist datum 178 may include ‘Hi Juhun ˜. It looks like you are missing Flashing and Membrane Overlap. Take a look at this design guidance for it.’ with a design guidance 150 attached along with design assist datum 178 showing steps to design ‘Flashing and Membrane Overlap.’ As shown in FIG. 12, design assist datum 178 may include ‘You are almost there for the Continuous Insulation! Let's go through this checklist to make sure your envelop is nice and sealed!’ along with a checklist that a user 128 can manipulate by clicking or checking the checking boxes of the checklist. In some embodiments, user interface 156 may display a user query button 1200 that a user 128 can manipulate to ask questions (e.g., user query 182). As a non-limiting example, user query 182 may include a question related to representative part model 120, design problem 146, design solution 148, component 116, and the like and processor 104 may generate user prompt 152 as a function of user query 182. As another non-limiting example, user query 182 may include a request for information related to representative part model 120, design problem 146, design solution 148, component 116, and the like and processor 104 may generate user prompt 152, design problem 146, design solution 148, or component 116 as a function of user query 182. As a non-limiting example, user prompt 152 may include text, image, video, icon, and the like.

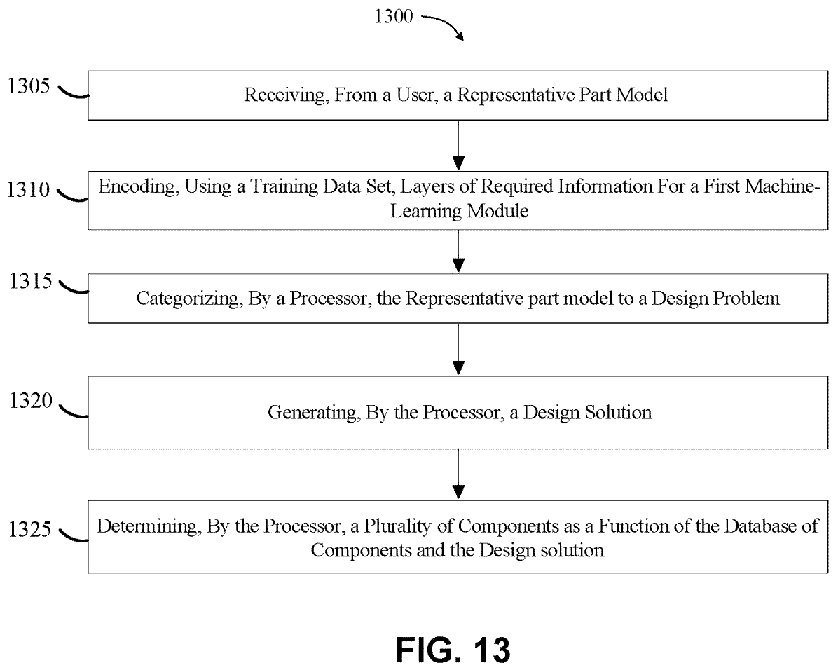

Referring now to FIG. 13, a method 1300 for determining and solving design problems using machine-learning is described. At step 1305, method 1300 includes receiving, from a user, a representative part model wherein the representative part model includes a computer model of a building design. In some cases, the representative part model includes a print of the building design. This step may be implemented as described above with reference to FIGS. 1-12, without limitation.

With continued reference to FIG. 13, at step 1310, method 1300 includes encoding, using a training data set, layers of required information for a first machine-learning module. This step may be implemented as described above with reference to FIGS. 1-12, without limitation.

With continued reference to FIG. 13, at step 1315, method 1300 includes categorizing, by a processor, representative part model to a design problem using a first machine-learning module, as a function of the representative part model. In some cases, the second machine-learning module includes a generative adversarial network. This step may be implemented as described above with reference to FIGS. 1-12, without limitation.

With continued reference to FIG. 13, at step 1320, method 1300 includes generating, by the processor, a design solution, in a visual format, using a second machine-learning module as a function of the design problem. In some cases, the design solution includes more than one solution. In some cases, each solution within the design solution is associated with a problem within the design problem. This step may be implemented as described above with reference to FIGS. 1-12, without limitation.

With continued reference to FIG. 13, at step 1325, method 1300 includes determining, by the processor, a plurality of components as a function of the database of components and the design solution. In some cases, the method further includes producing, by the processor, at least one building information modeling (BIM) integrated object as a function of the plurality of components, wherein the BIM integrated object is visual representation of a component. In some cases, the method further includes generating, by the processor, a modified part model as a function of the plurality of components. In some cases, generating, by the processor, the modified part model as a function of the plurality of components may include generating the modified part model as a function of user input.

With continued reference to FIG. 13, method 1300 may further include creating, by the processor, a user interface data structure including the plurality of components and transmitting, by the processor, the user interface data structure. In some cases transmitting, by the processor, may further include transmitting, by the processor, the user interface data structure to a graphical user interface (GUI), wherein the GUI is configured to receive the user interface data structure and display the plurality of components as a function of the user interface data structure.

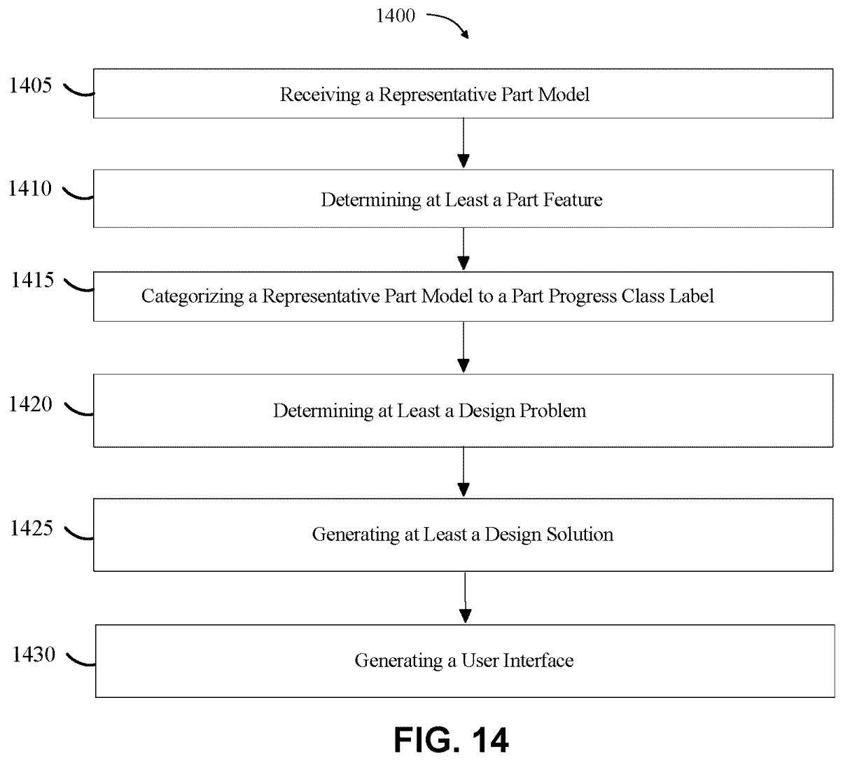

Referring now to FIG. 14, a flow diagram of an exemplary method 1400 for determining and solving design problems using machine learning is disclosed. The method 1400 contains a step 1405 of receiving, using at least a processor, a representative part model. In some embodiments, receiving the representative part model may include extracting the representative part model from a print using a machine vision system. These may be implemented as reference to FIGS. 1-13.

With continued reference to FIG. 14, method 1400 contains a step 1410 of determining, using at least a processor, at least a part feature of the representative part model. This may be implemented as reference to FIGS. 1-13.

With continued reference to FIG. 14, method 1400 contains a step 1415 of categorizing, using at least a processor, a representative part model to a part progress class label that defines a region class and a design progress state, wherein categorizing the representative part model includes determining the region class as a function of a design reference, wherein the design reference is queried from a part database as a function of the at least a part feature and the design reference includes design standards and determining the design progress state as a function of the design reference using a first machine-learning module. In some embodiments, categorizing the representative part model may include segmenting the representative part model into one or more building parts as a function of the at least a part feature and categorizing the one or more building parts to the part progress class label as a function of the design reference. In some embodiments, determining the design progress state may include generating first training data, wherein the first training data may include exemplary representative part models, exemplary design references correlated to exemplary design progress states, training the first machine-learning module using the first training data and determining the design progress state using the trained first machine-learning module. These may be implemented as reference to FIGS. 1-13.

With continued reference to FIG. 14, method 1400 contains a step 1420 of determining, using at least a processor, at least a design problem of a representative part model with a part progress class label. This may be implemented as reference to FIGS. 1-13.

With continued reference to FIG. 14, method 1400 contains a step 1425 of generating, using at least a processor, at least a design solution as a function of at least a design problem using a second machine-learning module. In some embodiments, generating the at least a design solution may include generating second training data, wherein the second training data may include exemplary design problems correlated to exemplary design solutions, training the second machine-learning module using the second training data and determining the at least a design solution using the trained second machine-learning module. In some embodiments, the at least a design solution may include a design guidance, wherein the design guidance may be configured to provide a guide to design the representative part model. These may be implemented as reference to FIGS. 1-13.

With continued reference to FIG. 14, method 1400 contains a step 1430 of generating, using at least a processor, a user interface displaying a representative part model with a part progress class label, at least a design problem, and at least a design solution on a remote device. In some embodiments, generating the user interface may include generating a user input field, wherein a user may query the representative part model from the part database using a keyword related to the part progress class label. These may be implemented as reference to FIGS. 1-13.

With continued reference to FIG. 14, in some embodiments, method 1400 may further include generating, using at least a processor, a design assist datum as a function of at least a design problem and at least a design solution and generating, using the at least a processor, a user interface displaying the design assist datum on a remote device. In some embodiments, method 1400 may further include receiving, using the at least a processor, a user query related to a displayed representative part model with the part progress class label, the design problem, and the design solution from the remote device, generating, using the at least a processor, a user prompt as a function of the user query and generating, using the at least a processor, the user interface displaying the user prompt on the remote device. In some embodiments, generating the user prompt may include generating language training data, wherein the language training data comprises exemplary user queries correlated to exemplary user prompts, wherein the language training data is extracted from the part database, training a large language model using the language training data and generating the user prompt as a function of the user prompt using the trained large language model. These may be implemented as reference to FIGS. 1-13.

It is to be noted that any one or more of the aspects and embodiments described herein may be conveniently implemented using one or more machines (e.g., one or more computing devices that are utilized as a user computing device for an electronic document, one or more server devices, such as a document server, etc.) programmed according to the teachings of the present specification, as will be apparent to those of ordinary skill in the computer art. Appropriate software coding can readily be prepared by skilled programmers based on the teachings of the present disclosure, as will be apparent to those of ordinary skill in the software art. Aspects and implementations discussed above employing software and/or software modules may also include appropriate hardware for assisting in the implementation of the machine executable instructions of the software and/or software module.

Such software may be a computer program product that employs a machine-readable storage medium. A machine-readable storage medium may be any medium that is capable of storing and/or encoding a sequence of instructions for execution by a machine (e.g., a computing device) and that causes the machine to perform any one of the methodologies and/or embodiments described herein. Examples of a machine-readable storage medium include, but are not limited to, a magnetic disk, an optical disc (e.g., CD, CD-R, DVD, DVD-R, etc.), a magneto-optical disk, a read-only memory “ROM” device, a random access memory “RAM” device, a magnetic card, an optical card, a solid-state memory device, an EPROM, an EEPROM, and any combinations thereof. A machine-readable medium, as used herein, is intended to include a single medium as well as a collection of physically separate media, such as, for example, a collection of compact discs or one or more hard disk drives in combination with a computer memory. As used herein, a machine-readable storage medium does not include transitory forms of signal transmission.

Such software may also include information (e.g., data) carried as a data signal on a data carrier, such as a carrier wave. For example, machine-executable information may be included as a data-carrying signal embodied in a data carrier in which the signal encodes a sequence of instruction, or portion thereof, for execution by a machine (e.g., a computing device) and any related information (e.g., data structures and data) that causes the machine to perform any one of the methodologies and/or embodiments described herein.

Examples of a computing device include, but are not limited to, an electronic book reading device, a computer workstation, a terminal computer, a server computer, a handheld device (e.g., a tablet computer, a smartphone, etc.), a web appliance, a network router, a network switch, a network bridge, any machine capable of executing a sequence of instructions that specify an action to be taken by that machine, and any combinations thereof. In one example, a computing device may include and/or be included in a kiosk.

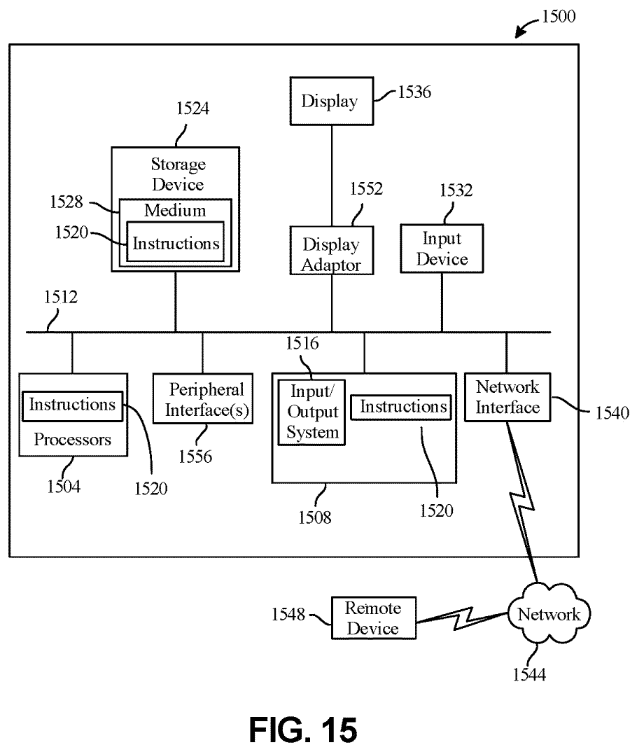

FIG. 15 shows a diagrammatic representation of one embodiment of a computing device in the exemplary form of a computer system 1500 within which a set of instructions for causing a control system to perform any one or more of the aspects and/or methodologies of the present disclosure may be executed. It is also contemplated that multiple computing devices may be utilized to implement a specially configured set of instructions for causing one or more of the devices to perform any one or more of the aspects and/or methodologies of the present disclosure. Computer system 1500 includes a processor 1504 and a memory 1508 that communicate with each other, and with other components, via a bus 1512. Bus 1512 may include any of several types of bus structures including, but not limited to, a memory bus, a memory controller, a peripheral bus, a local bus, and any combinations thereof, using any of a variety of bus architectures.

Processor 1504 may include any suitable processor, such as without limitation a processor incorporating logical circuitry for performing arithmetic and logical operations, such as an arithmetic and logic unit (ALU), which may be regulated with a state machine and directed by operational inputs from memory and/or sensors; processor 1504 may be organized according to Von Neumann and/or Harvard architecture as a non-limiting example. Processor 1504 may include, incorporate, and/or be incorporated in, without limitation, a microcontroller, microprocessor, digital signal processor (DSP), Field Programmable Gate Array (FPGA), Complex Programmable Logic Device (CPLD), Graphical Processing Unit (GPU), general purpose GPU, Tensor Processing Unit (TPU), analog or mixed signal processor, Trusted Platform Module (TPM), a floating point unit (FPU), and/or system on a chip (SoC)

Memory 1508 may include various components (e.g., machine-readable media) including, but not limited to, a random-access memory component, a read only component, and any combinations thereof. In one example, a basic input/output system 1516 (BIOS), including basic routines that help to transfer information between elements within computer system 1500, such as during start-up, may be stored in memory 1508. Memory 1508 may also include (e.g., stored on one or more machine-readable media) instructions (e.g., software) 1520 embodying any one or more of the aspects and/or methodologies of the present disclosure. In another example, memory 1508 may further include any number of program modules including, but not limited to, an operating system, one or more application programs, other program modules, program data, and any combinations thereof.

Computer system 1500 may also include a storage device 1524. Examples of a storage device (e.g., storage device 1524) include, but are not limited to, a hard disk drive, a magnetic disk drive, an optical disc drive in combination with an optical medium, a solid-state memory device, and any combinations thereof. Storage device 1524 may be connected to bus 1512 by an appropriate interface (not shown). Example interfaces include, but are not limited to, SCSI, advanced technology attachment (ATA), serial ATA, universal serial bus (USB), IEEE 1394 (FIREWIRE), and any combinations thereof. In one example, storage device 1524 (or one or more components thereof) may be removably interfaced with computer system 1500 (e.g., via an external port connector (not shown)). Particularly, storage device 1524 and an associated machine-readable medium 1528 may provide nonvolatile and/or volatile storage of machine-readable instructions, data structures, program modules, and/or other data for computer system 1500. In one example, software 1520 may reside, completely or partially, within machine-readable medium 1528. In another example, software 1520 may reside, completely or partially, within processor 1504.

Computer system 1500 may also include an input device 1532. In one example, a user of computer system 1500 may enter commands and/or other information into computer system 1500 via input device 1532. Examples of an input device 1532 include, but are not limited to, an alpha-numeric input device (e.g., a keyboard), a pointing device, a joystick, a gamepad, an audio input device (e.g., a microphone, a voice response system, etc.), a cursor control device (e.g., a mouse), a touchpad, an optical scanner, a video capture device (e.g., a still camera, a video camera), a touchscreen, and any combinations thereof. Input device 1532 may be interfaced to bus 1512 via any of a variety of interfaces (not shown) including, but not limited to, a serial interface, a parallel interface, a game port, a USB interface, a FIREWIRE interface, a direct interface to bus 1512, and any combinations thereof. Input device 1532 may include a touch screen interface that may be a part of or separate from display device 1536, discussed further below. Input device 1532 may be utilized as a user selection device for selecting one or more graphical representations in a graphical interface as described above.

A user may also input commands and/or other information to computer system 1500 via storage device 1524 (e.g., a removable disk drive, a flash drive, etc.) and/or network interface device 1540. A network interface device, such as network interface device 1540, may be utilized for connecting computer system 1500 to one or more of a variety of networks, such as network 1544, and one or more remote devices 1548 connected thereto. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network, such as network 1544, may employ a wired and/or a wireless mode of communication. In general, any network topology may be used. Information (e.g., data, software 1520, etc.) may be communicated to and/or from computer system 1500 via network interface device 1540.

Computer system 1500 may further include a video display adapter 1552 for communicating a displayable image to a display device, such as display device 1536. Examples of a display device include, but are not limited to, a liquid crystal display (LCD), a cathode ray tube (CRT), a plasma display, a light emitting diode (LED) display, and any combinations thereof. Display adapter 1552 and display device 1536 may be utilized in combination with processor 1504 to provide graphical representations of aspects of the present disclosure. In addition to a display device, computer system 1500 may include one or more other peripheral output devices including, but not limited to, an audio speaker, a printer, and any combinations thereof. Such peripheral output devices may be connected to bus 1512 via a peripheral interface 1556. Examples of a peripheral interface include, but are not limited to, a serial port, a USB connection, a FIREWIRE connection, a parallel connection, and any combinations thereof.

The foregoing has been a detailed description of illustrative embodiments of the invention. Various modifications and additions can be made without departing from the spirit and scope of this invention. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve methods, systems, and software according to the present disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. An apparatus for determining and solving design problems using machine learning, the apparatus comprising:
at least a processor; and
a memory communicatively connected to the at least a processor, the memory containing instructions configuring the at least a processor to:
receive a representative part model;
determine at least a part feature of the representative part model;
categorize the representative part model to a part progress class label that defines a region class and a design progress state, wherein categorizing the representative part model comprises:
determining the region class as a function of a design reference, wherein:
the design reference is queried from a part database as a function of the at least a part feature; and
the design reference comprises design standards; and
determining the design progress state as a function of the design reference using a first machine-learning module;
determine at least a design problem of the representative part model with the part progress class label;
generate at least a design solution as a function of the at least a design problem using a second machine-learning module; and
generate a user interface displaying the representative part model with the part progress class label, the at least a design problem, and the at least a design solution on a remote device.

2. The apparatus of claim 1, wherein receiving the representative part model comprises extracting the representative part model from a print using a machine vision system.

3. The apparatus of claim 1, wherein categorizing the representative part model comprises:
segmenting the representative part model into one or more building parts as a function of the at least a part feature; and
categorizing the one or more building parts to the part progress class label as a function of the design reference.

4. The apparatus of claim 1, wherein determining the design progress state comprises:
generating first training data, wherein the first training data comprises exemplary representative part models, exemplary design references correlated to exemplary design progress states;
training the first machine-learning module using the first training data; and
determining the design progress state using the trained first machine-learning module.

5. The apparatus of claim 1, wherein generating the at least a design solution comprises:
generating second training data, wherein the second training data comprises exemplary design problems correlated to exemplary design solutions;
training the second machine-learning module using the second training data; and
determining the at least a design solution using the trained second machine-learning module.

6. The apparatus of claim 1, wherein the at least a design solution comprises a design guidance, wherein the design guidance is configured to provide a guide to design the representative part model.

7. The apparatus of claim 1, wherein generating the user interface comprises generating a user input field, wherein a user queries the representative part model from the part database using a keyword related to the part progress class label.

8. The apparatus of claim 1, wherein the memory contains instructions configuring the at least a processor to:
generate a design assist datum as a function of the at least a design problem and the at least a design solution; and
generate the user interface displaying the design assist datum on the remote device.

9. The apparatus of claim 1, wherein the memory contains instructions configuring the at least a processor to:
receive a user query related to the displayed representative part model with the part progress class label, the design problem, and the at least a design solution from the remote device;
generate a user prompt as a function of the user query; and
generate the user interface displaying the user prompt on the remote device.

10. The apparatus of claim 9, wherein generating the user prompt comprises:
generating language training data, wherein the language training data comprises exemplary user queries correlated to exemplary user prompts, wherein the language training data is extracted from the part database;
training a large language model using the language training data; and
generating the user prompt as a function of the user prompt using the trained large language model.

11. A method for determining and solving design problems using machine learning, the method comprising:
receiving, using at least a processor, a representative part model;
determining, using the at least a processor, at least a part feature of the representative part model;
categorizing, using the at least a processor, the representative part model to a part progress class label that defines a region class and a design progress state,
wherein categorizing the representative part model comprises:
determining the region class as a function of a design reference, wherein:
the design reference is queried from a part database as a function of the at least a part feature; and
the design reference comprises design standards; and
determining the design progress state as a function of the design reference using a first machine-learning module;
determining, using the at least a processor, at least a design problem of the representative part model with the part progress class label;
generating, using the at least a processor, at least a design solution as a function of the at least a design problem using a second machine-learning module; and
generating, using the at least a processor, a user interface displaying the representative part model with the part progress class label, the at least a design problem, and the at least a design solution on a remote device.

12. The method of claim 11, wherein receiving the representative part model comprises extracting the representative part model from a print using a machine vision system.

13. The method of claim 11, wherein categorizing the representative part model comprises:
segmenting the representative part model into one or more building parts as a function of the at least a part feature; and
categorizing the one or more building parts to the part progress class label as a function of the design reference.

14. The method of claim 11, wherein determining the design progress state comprises:
generating first training data, wherein the first training data comprises exemplary representative part models, exemplary design references correlated to exemplary design progress states;
training the first machine-learning module using the first training data; and
determining the design progress state using the trained first machine-learning module.

15. The method of claim 11, wherein generating the at least a design solution comprises:
generating second training data, wherein the second training data comprises exemplary design problems correlated to exemplary design solutions;
training the second machine-learning module using the second training data; and
determining the at least a design solution using the trained second machine-learning module.

16. The method of claim 11, wherein the at least a design solution comprises a design guidance, wherein the design guidance is configured to provide a guide to design the representative part model.

17. The method of claim 11, wherein generating the user interface comprises generating a user input field, wherein a user queries the representative part model from the part database using a keyword related to the part progress class label.

18. The method of claim 11, further comprising:
generating, using the at least a processor, a design assist datum as a function of the at least a design problem and the at least a design solution; and
generating, using the at least a processor, the user interface displaying the design assist datum on the remote device.

19. The method of claim 11, further comprising:
receiving, using the at least a processor, a user query related to the displayed representative part model with the part progress class label, the design problem, and the at least a design solution from the remote device;
generating, using the at least a processor, a user prompt as a function of the user query; and
generating, using the at least a processor, the user interface displaying the user prompt on the remote device.

20. The method of claim 19, wherein generating the user prompt comprises:
generating language training data, wherein the language training data comprises exemplary user queries correlated to exemplary user prompts, wherein the language training data is extracted from the part database;
training a large language model using the language training data; and
generating the user prompt as a function of the user prompt using the trained large language model.
